(19) United States
(12) Patent Application Publication
(10) Pub. No.: US 2026/0231839 A1
(43) Pub. Date: Aug. 6, 2026

(54) SEMICONDUCTOR DEVICE

(71) Applicant: Renesas Electronics Corporation, Tokyo (JP)

(72) Inventors: Yasutaka NAKASHIBA, Tokyo (JP); Toshiyuki HATA, Tokyo (JP)

(21) Appl. No.: 19/443,797

(22) Filed: Jan. 8, 2026

(30) Foreign Application Priority Data
Feb. 5, 2025 (JP) 2025-017800

(51) Int. Cl. H10W 90/00; H10W 70/40; H10W 74/10

(52) U.S. Cl. CPC H10W 90/811; H10W 70/411; H10W 70/475; H10W 74/111; H10W 90/756

(57) ABSTRACT

A semiconductor device includes: a first die pad; a second die pad; a third die pad; a first semiconductor chip arranged on the first die pad; a second semiconductor chip arranged on the second die pad; an insulator arranged on the third die pad via a bonding material; a metal film arranged on the insulator; a first wire; a second wire; and a sealing body sealing these members. The first wire electrically connects a first pad of the first semiconductor chip and the third die pad. The second wire electrically connects a second pad of the second semiconductor chip and the metal film.

### CROSS-REFERENCE TO RELATED APPLICATION

The disclosure of Japanese Patent Application No. 2025-017800 filed on February 5, 2025, including the specification, drawings and abstract is incorporated herein by reference in its entirety.

### BACKGROUND

The present invention relates to a semiconductor device, and is suitably applicable to, for example, a semiconductor device including a plurality of semiconductor chips.

A semiconductor device of a semiconductor package type can be manufactured by mounting a semiconductor chip on a die pad, electrically connecting a pad electrode of the semiconductor chips and a lead via a wire, and sealing these members by resin.

There is disclosed technique listed below.

[Patent Document 1] Japanese Unexamined Patent Application Publication No. 2023-181601

The Patent Document 1 describes a technique in which two coils provided on another semiconductor chip are inductively coupled in order to transmit a signal from one semiconductor chip to the another semiconductor chip, thereby transmitting an electric signal.

### SUMMARY

The present inventors have studied a digital isolator for transmitting signals between two semiconductor chips. It is desirable to reduce a cost for manufacturing a semiconductor device including the digital isolator. Alternatively, it is desirable to improve reliability of the semiconductor device including the digital isolator.

Other objects and novel characteristics will become apparent from the description of the present specification and the accompanying drawings.

A semiconductor device according to one embodiment includes: a first die pad; a second die pad; a third die pad; a first semiconductor chip arranged on the first die pad; a second semiconductor chip arranged on the second die pad; an insulator arranged on the third die pad via a first bonding material; a metal film arranged on the insulator; a first wire; a second wire; and a sealing body for sealing these members. The first wire electrically connects a first pad of the first semiconductor chip and the third die pad. The second wire electrically connects a second pad of the second semiconductor chip and the metal film.

According to one embodiment, the cost for manufacturing the semiconductor device can be reduced. Alternatively, the reliability of the semiconductor device can be improved. Alternatively, the cost for manufacturing the semiconductor device can be reduced, and the reliability of the semiconductor device can be improved.

### BRIEF DESCRIPTIONS OF THE DRAWINGS

FIG. 1 is a circuit diagram illustrating an inverter circuit using a semiconductor device according to a first embodiment.

FIG. 2 is a top view illustrating the semiconductor device according to the first embodiment.

FIG. 3 is a perspective plan view illustrating the semiconductor device according to the first embodiment.

FIG. 4 is a perspective plan view illustrating the semiconductor device according to the first embodiment.

FIG. 5 is a bottom view illustrating the semiconductor device according to the first embodiment.

FIG. 6 is a cross-sectional view illustrating the semiconductor device according to the first embodiment.

FIG. 7 is a cross-sectional view illustrating the semiconductor device according to the first embodiment.

FIG. 8 is a cross-sectional view schematically illustrating a part of the semiconductor device according to the first embodiment.

FIG. 9 is a cross-sectional view illustrating a step of manufacturing the semiconductor device according to the first embodiment.

FIG. 10 is a cross-sectional view illustrating a step of manufacturing the semiconductor device according to the first embodiment.

FIG. 11 is a cross-sectional view illustrating a step of manufacturing the semiconductor device according to the first embodiment.

FIG. 12 is a cross-sectional view illustrating a step of manufacturing the semiconductor device according to the first embodiment.

FIG. 13 is a cross-sectional view illustrating a step of manufacturing a semiconductor device according to a first modification example.

FIG. 14 is a cross-sectional view illustrating a step of manufacturing the semiconductor device according to the first modification example.

FIG. 15 is a cross-sectional view illustrating a step of manufacturing the semiconductor device according to the first modification example.

FIG. 16 is a cross-sectional view illustrating a step of manufacturing the semiconductor device according to the first modification example.

FIG. 17 is a cross-sectional view illustrating a step of manufacturing a semiconductor device according to a second modification example.

FIG. 18 is a cross-sectional view illustrating a step of manufacturing the semiconductor device according to the second modification example.

FIG. 19 is a cross-sectional view illustrating a step of manufacturing the semiconductor device according to the second modification example.

FIG. 20 is a cross-sectional view illustrating a step of manufacturing the semiconductor device according to the second modification example.

FIG. 21 is a cross-sectional view illustrating a step of manufacturing a semiconductor device according to a third modification example.

FIG. 22 is a cross-sectional view illustrating a step of manufacturing the semiconductor device according to the third modification example.

FIG. 23 is a cross-sectional view illustrating a step of manufacturing the semiconductor device according to the third modification example.

FIG. 24 is a cross-sectional view illustrating a step of manufacturing the semiconductor device according to the third modification example.

FIG. 25 is a cross-sectional view illustrating a step of manufacturing the semiconductor device according to the third modification example.

FIG. 26 is a cross-sectional view illustrating a step of manufacturing the semiconductor device according to the third modification example.

FIG. 27 is a cross-sectional view illustrating a step of manufacturing the semiconductor device according to the third modification example.

FIG. 28 is a cross-sectional view illustrating a step of manufacturing a semiconductor device according to a fourth modification example.

FIG. 29 is a cross-sectional view illustrating a step of manufacturing the semiconductor device according to the fourth modification example.

FIG. 30 is a cross-sectional view illustrating a step of manufacturing the semiconductor device according to the fourth modification example.

FIG. 31 is a cross-sectional view illustrating a step of manufacturing the semiconductor device according to the fourth modification example.

FIG. 32 is a cross-sectional view illustrating a step of manufacturing the semiconductor device according to the fourth modification example.

FIG. 33 is a circuit diagram illustrating an inverter circuit using a semiconductor device according to a second embodiment.

FIG. 34 is a perspective plan view illustrating the semiconductor device according to the second embodiment.

FIG. 35 is a perspective plan view illustrating the semiconductor device according to the second embodiment.

FIG. 36 is a cross-sectional view schematically illustrating a part of the semiconductor device according to the second embodiment.

FIG. 37 is a cross-sectional view schematically illustrating a part of the semiconductor device according to the second embodiment.

FIG. 38 is a perspective plan view illustrating a semiconductor device according to a third embodiment.

FIG. 39 is a perspective plan view illustrating the semiconductor device according to the third embodiment.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, embodiments will be described in detail with reference to the accompanying drawings. Note that components having the same function are denoted with the same reference symbols throughout all the drawings for describing the embodiments, and the repetitive description thereof will be omitted. In addition, the description of the same or similar portions is not repeated in principle unless otherwise particularly required in the following embodiments.

Also, in drawings used in the embodiments, even a cross-sectional view may be not hatched so as to make the drawings easy to see. In addition, even a plan view may be hatched so as to make the drawings easy to see.

### FIRST EMBODIMENT

### CIRCUIT CONFIGURATION

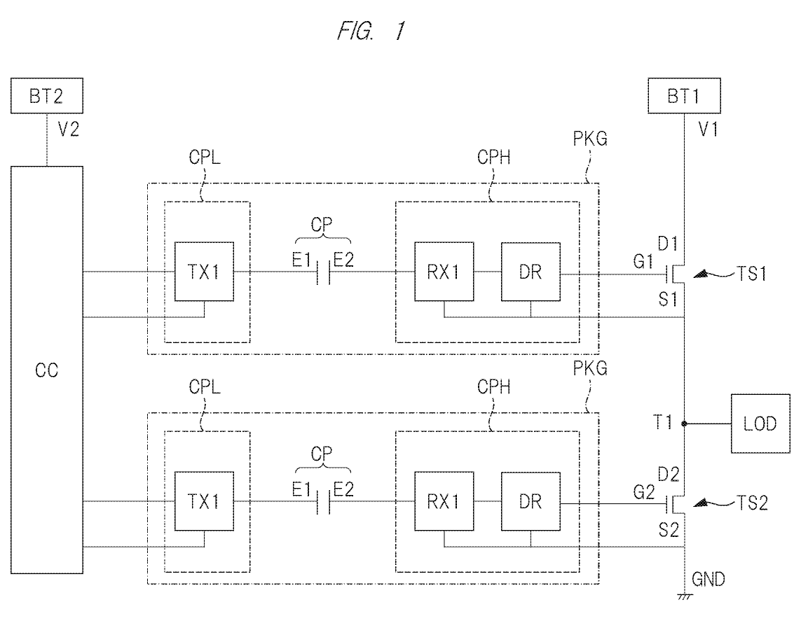

FIG. 1 is a circuit diagram illustrating an inverter circuit using a semiconductor device PKG according to a first embodiment. In FIG. 1, a part with a symbol CPH surrounded with a dotted line is formed in a semiconductor chip CPH, a part with a symbol CPL surrounded with a dotted line is formed in a semiconductor chip CPL, and a part with a symbol PKG surrounded with a dashed dotted line is formed in a semiconductor device PKG. The inverter circuit illustrated in FIG. 1 uses two semiconductor devices PKG. A circuit configuration of one semiconductor device PKG connected to a power transistor TS2 is basically the same as a circuit configuration of the other semiconductor device PKG connected to a power transistor TS1.

The semiconductor device PKG used in the inverter circuit illustrated in FIG. 1 includes two semiconductor chips CPL and CPH and a capacitor (capacitor element) CP. A transmitter circuit TX1 is formed in the semiconductor chip CPL. A receiver circuit RX1 and a driver circuit (controller circuit) DR are formed in the semiconductor chip CPH. The inverter circuit illustrated in FIG. 1 also includes a controller circuit CC. The controller circuit CC is formed in another semiconductor chip provided outside the semiconductor device PKG.

The transmitter circuit TX1 and the receiver circuit RX1 are circuits for transmitting a signal from the controller circuit CC to the driver circuit DR. The transmitter circuit TX1 converts a signal transmitted from the controller circuit CC to the transmitter circuit TX1, and transmits the converted signal to the receiver circuit RX1 via the capacitor CP. The receiver circuit RX1 receives and converts the signal from the transmitter circuit TX1 via the capacitor CP, and transmits the converted signal to the driver circuit DR.

The inverter circuit illustrated in FIG. 1 includes the power transistors TS1 and TS2. The power transistor TS1 is a transistor for high-side switch (high-potential switch), and the power transistor TS2 is a transistor for low-side switch (low-potential switch). Each of the power transistor TS1 and the power transistor TS2 is formed in a different semiconductor chip provided outside the semiconductor device PKG.

The following description will be made about a case in which the power transistors TS1 and TS2 are metal oxide semiconductor field effect transistors (MOSFETs). An insulated gate bipolar transistor (IGBT) can be used as each of the power transistors TS1 and TS2. In this case, in the following description about the power transistors TS1 and TS2, terms “source” and “drain” are rephrased as terms “emitter” and “collector,” respectively,.

In the present application, a term “MOSFET” described here includes not only a metal insulator semiconductor field effect transistor (MISFET) using an oxide film (silicon oxide film) for a gate insulating film but also a MISFET using an insulating film other than the oxide film for the gate insulating film.

The power transistor TS1 and the power transistor TS2 are connected in series. A source S1 of the power transistor TS1 is connected to a drain D2 of the power transistor TS2. A power supply potential (power supply voltage) V1 is supplied from a power supply (battery) BT1 to a drain D1 of the power transistor TS1. A power supply potential (power supply voltage) V2 is supplied from a power supply (battery) BT2 to the controller circuit CC. The power supply potential V1 supplied to the drain D1 of the power transistor TS1 is much higher than the power supply potential V2 (for example, several V to several tens of V) supplied to the controller circuit CC, and is, for example, 100 V or more (several hundreds of V). A reference potential such as ground potential (GND) lower than the power supply potential V1 is supplied to a source S2 of the power transistor TS2. Each of a gate G1 of the power transistor TS1 and a gate G2 of the power transistor TS2 is connected to the driver circuit DR.

The semiconductor devices PKG, the number of which is the same as that of the power transistors TS1, TS2, are used in the first embodiment. In this case, the driver circuit DR of the semiconductor device PKG provided for the power transistor TS1 controls the voltage of the gate G1 of the power transistor TS1, and the driver circuit DR of the semiconductor device PKG provided for the power transistor TS2 controls the voltage of the gate G2 of the power transistor TS2.

The operations of the power transistor TR1, TR2 can be controlled by controlling the gate voltage supplied from the driver circuit DR to the gate (G1, G2) of the power transistor TS1, TS2 in response to a signal supplied from the controller circuit CC to the driver circuit DR via the transmitter circuit TX1, the capacitor CP, and the receiver circuit RX1.

A terminal T1 provided between the source S1 of the power transistor TS1 and the drain D2 of the power transistor TS2 is an output terminal of the inverter circuit. The terminal T1 is connected to a load LOD. The load LOD is, for example, a coil of a motor. A direct-current power supplied to the inverter circuit is converted into an alternating-current power by the inverter circuit and is supplied to the load LOD.

The capacitor CP is provided between the transmitter circuit TX1 and the receiver circuit RX1. The controller circuit CC can transmit a signal to the driver circuit DR via the transmitter circuit TX1, the capacitor CP, and the receiver circuit RX1.

The capacitor CP is made of a pair of electrodes E1 and E2, and a capacitive insulating film between the electrodes E1 and E2. The electrodes E1 and E2 are not connected via a conductor. The electrode E1 of the capacitor CP is electrically connected to the transmitter circuit TX1 via a conductor, and the electrode E2 of the capacitor CP is electrically connected to the receiver circuit RX1 via a conductor. The capacitor CP is charged or discharged in response to a signal transmitted from the transmitter circuit TX1 to the electrode E1 of the capacitor CP. The receiver circuit RX1 can detect a current caused by the charging or discharging of the capacitor CP as a current flowing between the electrode E2 of the capacitor CP and the receiver circuit RX1. In use of this technique, a signal is transmitted from the transmitter circuit TX1 to the electrode E1 of the capacitor CP to charge or discharge the capacitor CP, and a current which is generated in response to the charging or discharging is detected (received) by the receiver circuit RX1, and therefore, a signal in response to the signal transmitted by the transmitter circuit TX1 can be received by the receiver circuit RX1. Thereby, a signal can be transmitted between the semiconductor chip CPL and the semiconductor chip CPH.

As described above, the semiconductor chip CPL and the semiconductor chip CPH are different from each other in level of power supply voltage. The semiconductor chip CPL and the semiconductor chip CPH are different from each other also in level of reference potential (reference voltage). For example, the semiconductor chip CPL is electrically connected to a low-voltage region including a circuit (such as the controller circuit CC) operated or driven at a low reference potential (such as 0 V) via a wire BW, a lead LD or the like described later. To the contrary, the semiconductor chip CPH is electrically connected to a high-voltage region including a circuit (such as the power transistor TS1) operated or driven at a reference potential (such as 100 V or more) higher than the reference potential and a circuit (such as the power transistor TS2) operated or driven at the same voltage as the reference potential via a wire BW, a leads LD or the like described later. However, since signals are transmitted between the semiconductor chips CPL and CPH via the capacitor CP, the signals can be transmitted/received between circuits with different voltages.

Note that FIG. 1 illustrates a case in which the controller circuit CC is included in a semiconductor chip other than the semiconductor chips CPH and CPL. However, as another form, the controller circuit CC may be partially or entirely included in the semiconductor chip CPL.

A transceiver circuit may be used instead of the transmitter circuit TX1, and a transceiver circuit may be used instead of the receiver circuit RX1. In this case, the signal can be bidirectionally transmitted between the semiconductor chip CPL and the semiconductor chip CPH. Specifically, the signal can be transmitted from the transceiver circuit (TX1) in the semiconductor chip CPL to the transceiver circuit (RX1) in the semiconductor chip CPH via the capacitor CP, and the signal can be transmitted from the transceiver circuit (RX1) in the semiconductor chip CPH to the transceiver circuit (TX1) in the semiconductor chip CPL via the capacitor CP.

### CONFIGURATION OF SEMICONDUCTOR DEVICE

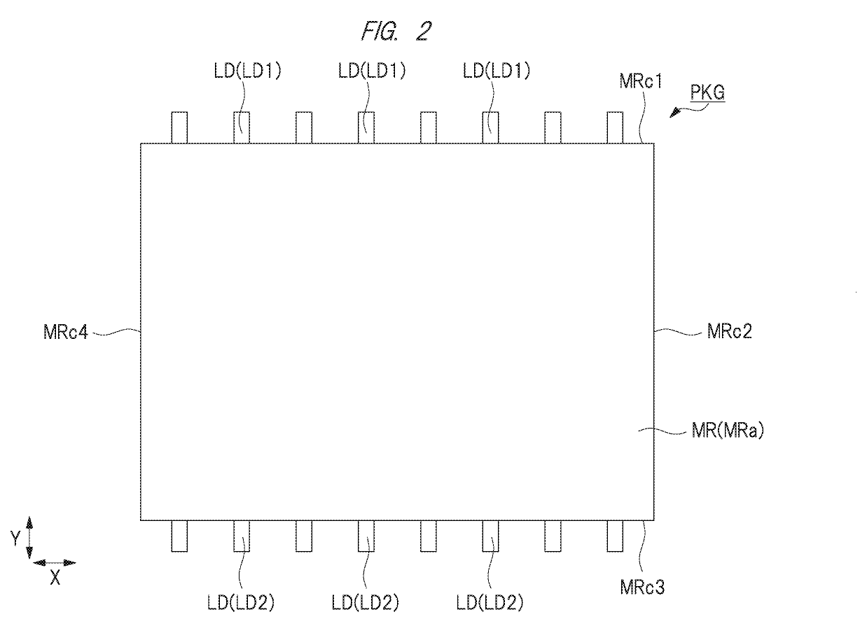

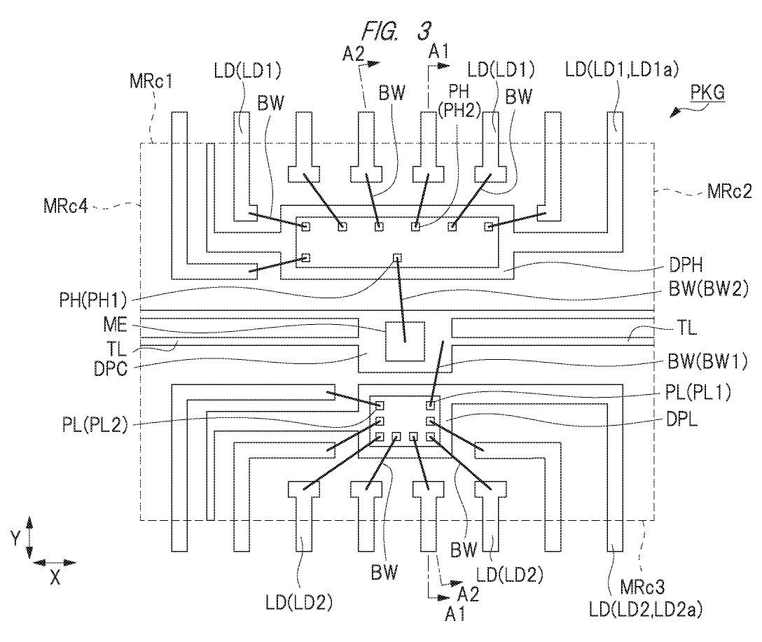

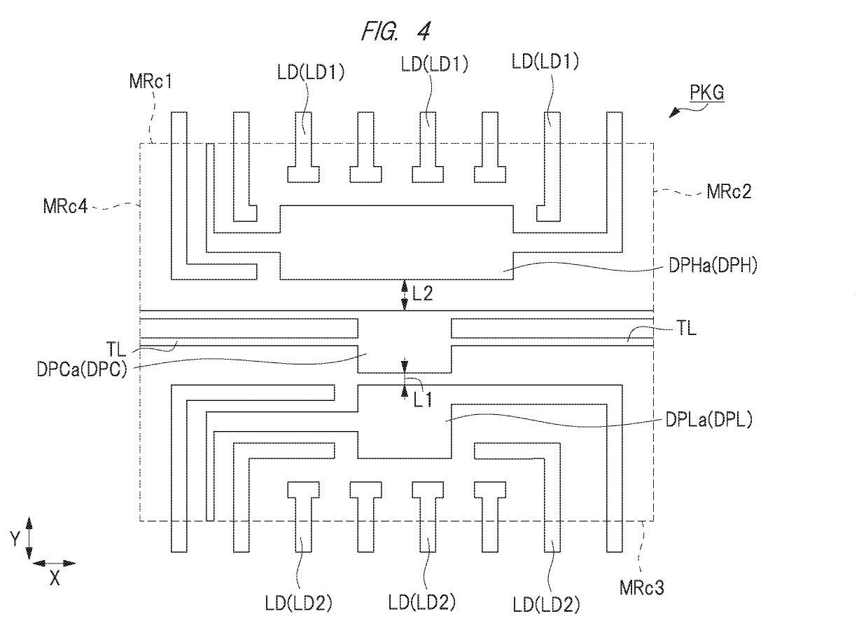

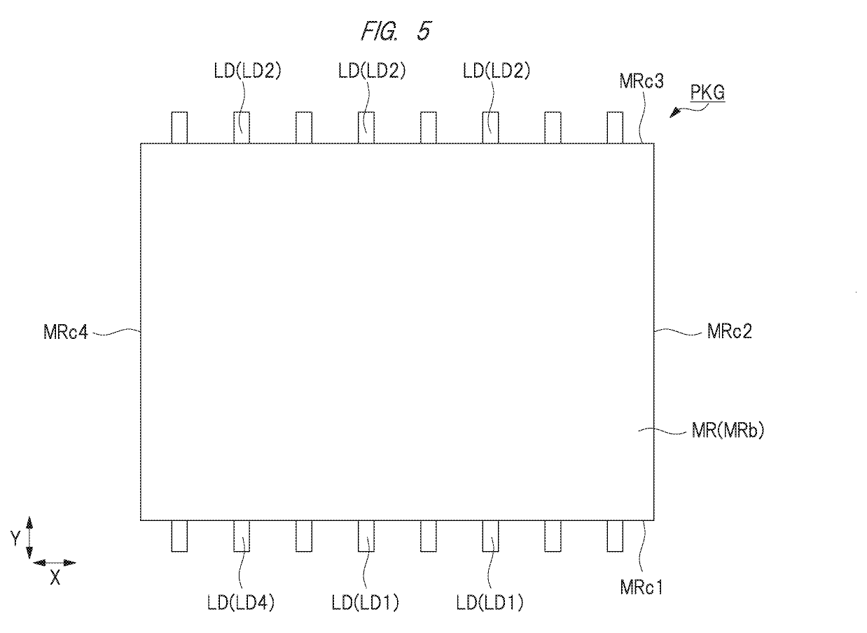

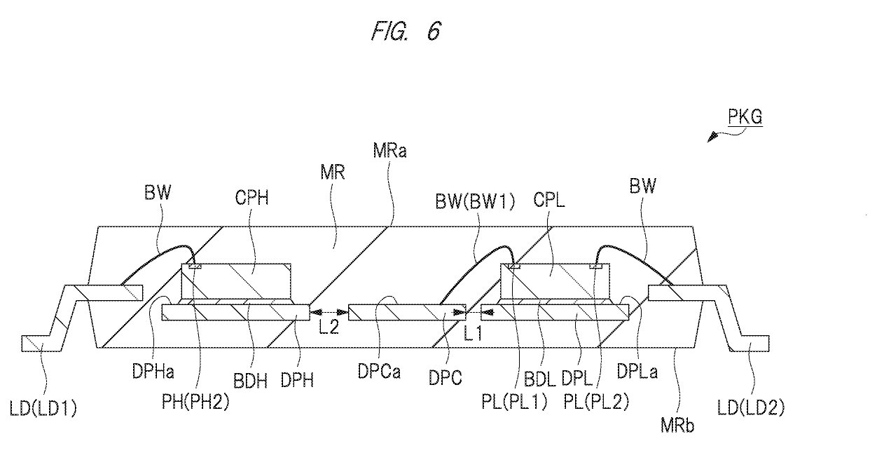

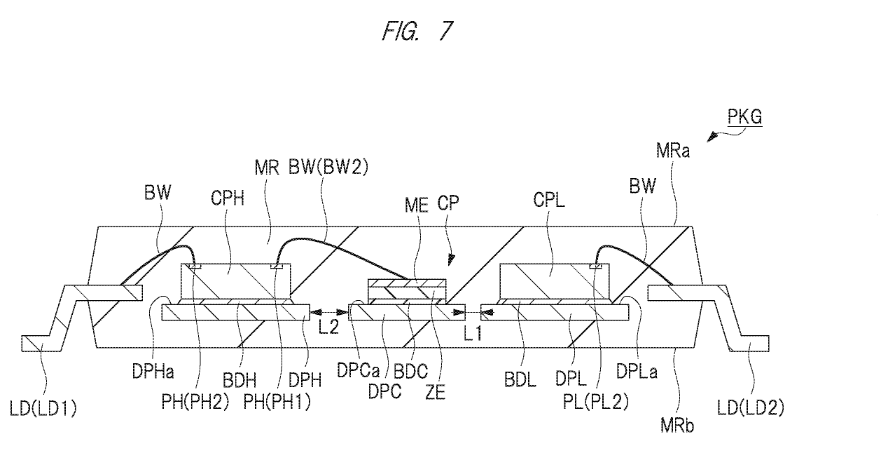

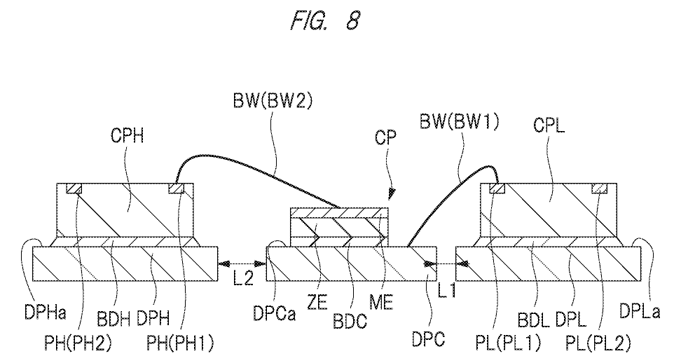

FIG. 2 is a top view illustrating the semiconductor device PKG according to the first embodiment, FIGS. 3 and 4 are perspective plan views illustrating the semiconductor device PKG, FIG. 5 is a bottom view (backside view) illustrating the semiconductor device PKG, and FIGS. 6 and 7 are cross-sectional views illustrating the semiconductor device PKG. FIG. 3 is a perspective plan view illustrating an upper side of the semiconductor device PKG in see-through view of a sealing body MR. FIG. 4 is a perspective plan view illustrating an upper side of the semiconductor device PKG in see-through view of the wire BW, the semiconductor chips CPH, CPL, a metal film ME, an insulator ZE, and bonding materials BDC, BDH, BDL in FIG. 3. In FIGS. 3 and 4, an outer peripheral position of the sealing body MR is illustrated with a dotted line. The cross-sectional view of the semiconductor device PKG taken along the line A1-A1 of FIG. 3 almost corresponds to FIG. 6, and the cross-sectional view of the semiconductor device PKG taken along the line A2-A2 of FIG. 3 almost corresponds to FIG. 7. FIGS. 2 to 5 illustrate an X direction and a Y direction. The X direction and the Y direction described here cross each other, and more specifically are perpendicular to each other. FIG. 8 is a cross-sectional view schematically illustrating a part of the semiconductor device PKG. FIG. 8 illustrates a connection relation among the semiconductor chip CPL, the capacitor CP, and the semiconductor chip CPH via the wire BW. The sealing body MR is not illustrated in FIG. 8.

The semiconductor device (semiconductor package) PKG according to the first embodiment illustrated in FIGS. 2 to 8 is a semiconductor device of a resin-sealing type semiconductor package form. In this case, this is a semiconductor device of a small outline package (SOP) type. A configuration of the semiconductor device PKG will be described below with reference to FIGS. 2 to 8.

The semiconductor device PKG according to the first embodiment illustrated in FIGS. 2 to 8 includes the semiconductor chip CPH, the semiconductor chip CPL, the capacitor CP, a die pad DPH, a die pad DPL, a die pad DPC, a plurality of wires (bonding wires) BW, a plurality of leads LD, and the sealing body MR for sealing these members.

The sealing body MR as a resin sealing body is made of a resin material such as thermosetting resin material, and may contain a filler or the like. For example, the sealing body MR may be made of filler-containing epoxy resin or the like.

The sealing body MR has an upper surface MRa as one main surface, a lower surface (back surface, bottom surface) MRb as the other main surface opposite to the upper surface MRa, and side surfaces MRc1, MRc2, MRc3, and MRc4 crossing the upper surface MRa and the lower surface MRb.

The side surfaces MRc1 and MRc3 are substantially parallel to the X direction, and the side surfaces MRc2 and MRc4 are substantially parallel to the Y direction. In the sealing body MR, the side surface MRc1 and the side surface MRc3 are opposite to each other, the side surface MRc2 and the side surface MRc4 are opposite to each other, the side surface MRc1 crosses the side surfaces MRc2 and MRc4, and the side surface MRc3 crosses the side surfaces MRc2 and MRc4. The upper surface MRa and the lower surface MRb are surfaces that are in parallel to both the X direction and the Y direction. The planar shape of the sealing body MR is, for example, rectangular.

One part of each of the leads LD of the semiconductor device PKG is sealed in the sealing body MR, and the other part thereof protrudes outward from the side surface of the sealing body MR. The part of the lead LD, which is positioned in the sealing body MR, is referred to as inner lead, and the part thereof, which is positioned outside the sealing body MR, is referred to as outer lead. A plated layer (not illustrated) such as solder plated layer may be formed in the outer lead of the lead LD.

Note that the semiconductor device PKG according to the first embodiment is configured such that the part of each lead LD protrudes from the side surface of the sealing body MR, and the following description will be made based on this configuration. However, the present invention is not limited to this configuration. For example, the present invention is also applicable to a small outline nonleaded package (SON) configuration or the like in which each lead LD hardly protrudes from the side surface of the sealing body MR while a part of each lead LD is exposed from the lower surface MRb of the sealing body MR.

The plurality of leads LD of the semiconductor device PKG includes a plurality of leads LD1 close to the side surface MRc1 of the sealing body MR and a plurality of leads LD2 close to the side surface MRc3 of the sealing body MR. In the case of FIGS. 2 to 5, no lead LD is arranged to be close to the side surfaces MRc2 and MRc4 of the sealing body MR. The outer lead of each lead LD1 protrudes outward from the side surface MRc1 of the sealing body MR. The outer lead of each lead LD2 protrudes outward from the side surface MRc3 of the sealing body MR. The outer lead of each lead LD is processed to be bent such that the lower surface of the outer lead around its end is positioned substantially on the same plane as the lower surface MRb of the sealing body MR. The outer lead of the lead LD functions as an external connection terminal (external terminal) of the semiconductor device PKG.

The die pad DPL is a chip mounting portion on which the semiconductor chip CPL is mounted, and the die pad DPH is a chip mounting portion on which the semiconductor chip CPH is mounted. The die pad DPC is a capacitor mounting portion on which a part of the capacitor CP is mounted. The die pad DPC is arranged between the die pad DPH and the die pad DPL in the Y direction. The die pad DPH, the die pad DPC, and the die pad DPL are spaced apart from one another. Specifically, the die pad DPH and the die pad DPC are spaced apart from each other in the Y direction, and the die pad DPL and the die pad DPC are spaced apart from each other in the Y direction. The distance (gap) L1 between the die pad DPL and the die pad DPC is smaller than the distance (gap) L2 between the die pad DPH and the die pad DPC. A part of the sealing body MR is arranged between the die pad DPH and the die pad DPC and between the die pad DPL and the die pad DPC.

The die pad DPH among the die pads DPH, DPL, and DPC is close to the side surface MRc1 of the sealing body MR, and the die pad DPL among them is close to the side surface MRc3 of the sealing body MR. That is, in the Y direction, the die pad DPC is arranged between the die pad DPL and the die pad DPH, the die pad DPH is arranged between the die pad DPC and the side surface MRc1 of the sealing body MR, and the die pad DPL is arranged between the die pad DPC and the side surface MRc3 of the sealing body MR. The die pads DPC, DPH, and DPL are sealed in the sealing body MR, and are not exposed from the sealing body MR.

Each of the die pads DPC, DPH, DPL and the leads LD is made of a conductor, more preferably made of a metal material such as copper (Cu) or copper alloy. The die pads DPC, DPH, DPL and the leads LD are preferably made of the same material as one another. In that way, the semiconductor device PKG using the lead frame can be easily manufactured.

The die pad DPH has an upper surface DPHa as one main surface on which the semiconductor chip CPH is mounted, a lower surface as the other main surface opposite to the upper surface DPHa, two side surfaces substantially parallel to the X direction, and two side surfaces substantially parallel to the Y direction. The die pad DPL has an upper surface DPLa as one main surface on which the semiconductor chip CPL is mounted, a lower surface as the other main surface opposite to the upper surface, two side surfaces substantially parallel to the X direction, and two side surfaces substantially parallel to the Y direction. The die pad DPC has an upper surface DPCa as one main surface on which a part of the capacitor CP is mounted, a lower surface as the other main surface opposite to the upper surface DPCa, two side surfaces substantially parallel to the X direction, and two side surfaces substantially parallel to the Y direction. The upper surface DPHa and the lower surface of the die pad DPH, the upper surface DPLa and the lower surface of the die pad DPL, and the upper surface DPCa and the lower surface of the die pad DPC are substantially parallel to both the X direction and the Y direction. The planar shapes of the die pads DPC, DPH, and DPL are, for example, rectangular.

The inner lead of the lead LD1a among the leads LD1 is integrally coupled to the die pad DPH. The lead LD1a functions as a suspending lead for supporting the die pad DPH on a lead frame at the time of the manufacturing of the semiconductor device PKG. The inner lead of the lead LD2a among the leads LD2 is integrally coupled to the die pad DPL. The lead LD2a functions as a suspending lead for supporting the die pad DPL on the lead frame at the time of the manufacturing of the semiconductor device PKG. A suspending lead TL is integrally coupled to the die pad DPC.

Each of the semiconductor chips CPH and CPL has the main surface and the back surface opposite to the main surface. The planar shape of each of the semiconductor chips CPH and CPL is quadrangular, more preferably rectangular. In this case, each side of the rectangle is, for example, substantially parallel to the X direction or the Y direction. The planar dimension (planar area) of the semiconductor chip CPH is larger than the planar dimension (planar area) of the semiconductor chip CPL. The length of the semiconductor chip CPH in the X direction is larger than the length of the semiconductor chip CPL in the X direction.

The semiconductor chip CPH is arranged (mounted) on the upper surface DPHa of the die pad DPH via the bonding material (adhesive material, die bonding material) BDH. The back surface of the semiconductor chip CPH faces the upper surface DPHa of the die pad DPH via the bonding material BDH. The semiconductor chip CPL is arranged (mounted) on the upper surface DPLa of the die pad DPL via the bonding material (adhesive material, die bonding material) BDL. The back surface of the semiconductor chip CPL faces the upper surface DPLa of the die pad DPL via the bonding material BDL. The semiconductor chip CPL is included in the upper surface DPLa of the die pad DPL in plan view. The semiconductor chip CPH is included in the upper surface DPHa of the die pad DPH in plan view.

Note that the term “plan view” means viewing in a plane parallel to both X direction and the Y direction.

A conductive bonding material such as silver paste may be used as he bonding materials BDH and BDL. The back surface of the semiconductor chip CPH is bonded and fixed to the die pad DPH via the bonding material BDH, and the back surface of the semiconductor chip CPL is bonded and fixed to the die pad DPL via the bonding material BDL. The semiconductor chips CPH, CPL and the capacitor CP are sealed in the sealing body MR and are not exposed from the sealing body MR.

An insulating bonding material may be also used as the bonding materials BDH and BDL. However, if the conductive bonding material is used as the bonding materials BDH and BDL, it is advantageous that heat generated in the semiconductor chips CPH and CPL is easily conducted to the die pads DPH and DPL via the bonding materials BDH and BDL, respectively.

An insulator (insulating film) ZE is arranged (mounted) on the upper surface DPCa of the die pad DPC via the bonding material (adhesive material) BDC. A metal film (metal body) ME is arranged (formed) on the insulator ZE. Thus, the bonding material BDC is arranged between the die pad DPC and the insulator ZE, the insulator ZE is arranged between the bonding material BDC and the metal film ME, and the bonding material BDC and the insulator ZE are arranged between the die pad DPC and the metal film ME. The capacitor CP is made of the die pad DPC, the bonding material BDC, the insulator ZE, and the metal film ME. The metal film ME may be a metal plate. An insulating bonding material is preferably used as the bonding material BDC. In the first embodiment, a die attach film (DAF) is used. The insulator ZE and the metal film ME on the insulator ZE are included in the upper surface DPCa of the die pad DPC in plan view.

As described with reference to FIG. 1, the capacitor CP is made of the electrode E1, the electrode E2, and the capacitive insulating film between the electrode E1 and the electrode E2. The electrode E1 of the capacitor CP is made of the die pad DPC, the electrode E2 of the capacitor CP is made of the metal film ME, and the capacitive insulating film of the capacitor CP is made of the insulator ZE and the insulating bonding material BDC. That is, the insulator ZE and the insulating bonding material BDC, which function as the capacitive insulating film, are arranged between the metal film ME functioning as the electrode E2 and the die pad DPC functioning as the electrode E1.

The bonding material BDC may be insulating or conducting. The bonding material BDC when being insulating makes a part of the capacitive insulating film of the capacitor CP. To the contrary, the bonding material BDC when being conducting makes a part of the electrode E1 of the capacitor CP. That is, the conductive bonding material BDC and the die pad DPC make the electrode E1 of the capacitor CP. If the bonding material BDC is insulating, the effective area of the electrode E1 of the capacitor CP increases, thereby increasing the capacitance of the capacitor CP. Additionally, the capacitor CP can be electrically stabilized.

A plurality of pads PH is formed on the main surface of the semiconductor chip CPH. A plurality of pads PL is formed on the main surface of the semiconductor chip CPL. Note that the bonding pad, the bonding pad electrode, the pad electrode and the electrode are collectively referred to as pad.

Each pad PL on the semiconductor chip CPL is electrically connected to the circuit (such as the transmitter circuit TX1) formed in the semiconductor chip CPL via the internal wiring of the semiconductor chip CPL. Each pad PH on the semiconductor chip CPH is electrically connected to the circuit (such as the receiver circuit RX1 and the driver circuit DR) formed in the semiconductor chip CPH via the internal wiring of the semiconductor chip CPH.

The pads PL of the semiconductor chip CPL include a pad PL1 and a plurality of pads PL2. The pads PH of the semiconductor chip CPH include a pad PH1 and a plurality of pads PH2.

The pad PL1 of the semiconductor chip CPL is electrically connected to the die pad DPC (the electrode E1) via a wire BW. The wire BW connecting the pad PL1 of the semiconductor chip CPL and the die pad DPC is referred to as wire BW1. That is, one end of the wire BW1 is connected to the pad PL1 of the semiconductor chip CPL, and the other end of the wire BW1 is connected to the die pad DPC. The pads PL2 of the semiconductor chip CPL are electrically connected to the leads LD2 via wires BW, respectively. One end of the wire BW is connected to the pad PL2 of the semiconductor chip CPL, and the other end of the wire BW is connected to the inner lead of the lead LD2.

The pad PH1 of the semiconductor chip CPH is electrically connected to the metal film ME (the electrode E2) via a wire BW. The wire BW connecting the pad PH1 of the semiconductor chip CPH and the metal film ME is referred to as wire BW2. That is, one end of the wire BW2 is connected to the pad PH1 of the semiconductor chip CPH, and the other end of the wire BW2 is connected to the metal film ME. The pads PH2 of the semiconductor chip CPH are electrically connected to the leads LD1 via wires BW, respectively. That is, one end of the wire BW is connected to the pad PH2 of the semiconductor chip CPH, and the other end of the wire BW is connected to the inner lead of a lead LD1.

The wires BW are conductive wires. The wires BW are specifically made of a metal, and a gold (Au) wire, a copper (Cu) wire, an aluminum (Al) wire or the like is preferably used. The wires BW are sealed in the sealing body MR and are not exposed from the sealing body MR. A connected portion of each lead LD with the wire BW is the inner lead in the sealing body MR.

When the semiconductor device PKG is in use, the semiconductor chip CPL in the semiconductor device PKG is electrically connected to the circuit (specifically, the controller circuit CC) outside the semiconductor device PKG via the wires BW, the leads LD2, and the like. When the semiconductor device PKG is in use, the semiconductor chip CPH in the semiconductor device PKG is electrically connected to the circuit (specifically, the inverter circuit) outside the semiconductor device PKG via the wires BW, the leads LD1, and the like. When the semiconductor device PKG is in use, signals are transmitted between the semiconductor chip CPL and the semiconductor chip CPH via the wire BW1, the capacitor CP, and the wire BW2. The power supply potential V1 supplied to the inverter circuit made of the power transistors TS1 and TS2 is higher than the power supply potential V2 supplied to the controller circuit CC. The reference potential supplied to the circuit made of the power transistor TS1 is higher than the reference potential supplied to the controller circuit CC.

### STEPS OF MANUFACTURING SEMICONDUCTOR DEVICE

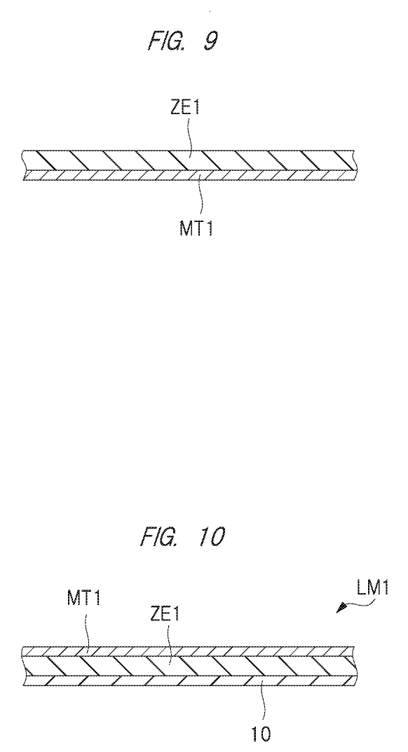

Next, steps of manufacturing (assembling) the semiconductor device PKG according to the first embodiment will be described. FIGS. 9 to 12 are cross-sectional views illustrating some steps of manufacturing the semiconductor device PKG according to the first embodiment.

The semiconductor chips CPH, CPL, a chip CH1A and the lead frame which integrally includes the die pads DPC, DPH, DPL and the leads LD are prepared in order to manufacture the semiconductor device PKG.

The chip CH1 can be prepared as follows. At first, an insulating film ZE1 is formed on a metal plate MT1 as illustrated in FIG. 9. The metal plate MT1 is made of, for example, copper, copper alloy, aluminum, aluminum alloy, or the like. And, for example, a permanent resist can be preferably used for the insulating film ZE1. For example, the insulating film ZE1 made of permanent resist is adhered to the metal plate MT1, and then, the insulating film ZE1 is hardened by a thermal processing (baking processing). Alternatively, the insulating film ZE1 made of permanent resist is formed on the metal film MT1 by a coating method, and then, the insulating film ZE1 is hardened by a thermal processing. Alternatively, the insulating film ZE1 made of a heat-resistant insulating material is formed on the metal plate MT1 by a coating method, and then, the insulating film ZE1 is hardened by a thermal processing.

Note that the permanent resist is a kind of resist used in semiconductor processes, and is chemically and mechanically stable for a long period of time. The permanent resist has high durability, chemical resistance, thermal stability, and mechanical strength. Thus, the permanent resist does not deteriorate for a long period of time, is difficult to be deteriorated by chemical agents, and is difficult to be deteriorated by even high temperature and physical stress. Thus, if the permanent resist is used for the insulator ZE (the insulating film ZE1), the reliability of the semiconductor device PKG can be further improved.

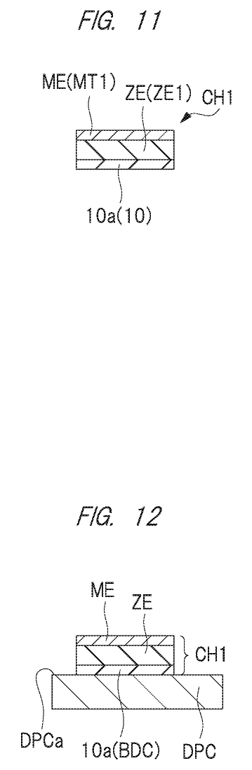

Thereafter, a DAF (die attach film) 10 is adhered to the insulating film ZE1 as illustrated in FIG. 10. Thereby, a layered material LM1, which is made of the DAF 10, the insulating film ZE1 on the DAF 10, and the metal plate MT1 on the insulating film ZE1, is formed. Thereafter, the layered material LM1 is cut into pieces by dicing. Thereby, the chip CH1 can be manufactured as illustrated in FIG. 11. The chip CH1 is made of a DAF10a, the insulator ZE on the DAF 10a, and the metal film ME on the insulator ZE. The insulator ZE of the chip CH1 is made of the cut insulating film ZE1, the metal film ME of the chip CH1 is made of the cut metal plate MT1, and the DAF 10a of the chip CH1 is made of the cut DAF 10.

Next, the semiconductor chip CPH is arranged on the upper surface DPHa of the die pad DPH in the lead frame via the bonding material BDH, and the semiconductor chip CPL is arranged on the upper surface DPLa of the die pad DPL via the bonding material BDL. The chip CH1 is arranged on the upper surface DPCa of the die pad DPC as illustrated in FIG. 12. At this time, each back surface of the semiconductor chips CPH and CPL is arranged to face the die pad. The chip CH1 is arranged such that the DAF 10a faces the die pad DPC. Thereafter, the bonding materials BDH, BDL and the DAF 10a are hardened by a thermal processings or the like. The hardened DAF 10a is to be the bonding material BDC. Thereby, the insulator ZE is arranged on the die pad DPC via the bonding material BDC (the DAF 10a in this case), and the metal film ME is arranged on the insulator ZE.

In the first embodiment, the DAF is used for the bonding material BDC. When the DAF is used for the bonding material BDC, a thickness of the bonding material BDC can be accurately controlled to be a desirable thickness, and thus, the capacitance of the capacitor CP can be easily controlled to a desired value.

In a modification example, a conductive DAF, epoxy resin, silver paste, or the like may be used for the bonding material BDC.

Next, a wire bonding step is performed. In the wire bonding step, the pad PL1 of the semiconductor chip CPL and the die pad DPC are electrically connected via the wire BW1. The pad PH1 of the semiconductor chip CPH and the metal film ME of the chip CH1 are electrically connected via the wire BW2. The pads PL2 of the semiconductor chip CPL and the leads LD2 are electrically connected via the wires BW, respectively. The pads PH2 of the semiconductor chip CPH and the leads LD1 are electrically connected via the wires BW, respectively.

Next, by resin sealing in the molding step, the sealing body MR is formed to seal the die pads DPC, DPH, DPL, the semiconductor chips CPH, CPL, the chip CH1, the wires BW, and the inner leads of the leads LD.

Next, a plated layer is formed on the outer lead of the lead LD exposed from the sealing body MR as needed. Thereafter, the lead LD is cut at a predetermined position outside the sealing body MR, and is separated from the lead frame.

Next, the outer lead of the lead LD protruding from the sealing body MR is bent (in lead processing).

In this way, the semiconductor device PKG illustrated in FIGS. 2 to 8 is manufactured.

### BACKGROUND OF STUDY

The present inventors have studied a digital isolator for transmitting signals between two semiconductor chips. The high dielectric breakdown (withstand voltage) of the digital isolator is required in order to improve the reliability of the semiconductor device including the digital isolator. The digital isolator is of magnetic insulation system (transformer type) and of capacitive insulation system (capacitor type).

The present inventors have studied the digital isolator of capacitor type. When the digital isolator of capacitor type is achieved by use of a semiconductor chip including a semiconductor substrate and a multilayer wiring formed on the semiconductor substrate as similar to the digital isolator of transformer type, the following problems arise.

When the digital isolator of capacitor type is achieved by use of the semiconductor chip, an upper electrode and a lower electrode of the capacitor are formed in the multilayer wiring of the semiconductor chip. In order to increase the dielectric breakdown of the capacitor, the distance between the upper electrode and the lower electrode of the capacitor is to be increased. For example, the distance between the upper electrode and the lower electrode of the capacitor is to be 20 μm or more. However, in order to increase the distance between the upper electrode and the lower electrode of the capacitor, the number of interlayer insulating films arranged between the upper electrode and the lower electrode of the capacitor is to be increased, and this increases the cost for manufacturing the semiconductor chip configuring the digital isolator of capacitor type. If the total thickness of the interlayer insulating films arranged between the upper electrode and the lower electrode of the capacitor is large, the semiconductor substrate is warped due to a difference between the thermal expansion rate of the semiconductor substrate and the thermal expansion rate of the interlayer insulating films, this may cause a risk of adverse influence on the manufacturing of the semiconductor chip.

### PRINCIPAL FEATURES AND EFFECTS

The semiconductor device PKG according to the first embodiment includes the die pad DPC, the insulator ZE arranged on the die pad DPC via the bonding material BDC, and the metal film ME arranged on the insulator ZE. The capacitor CP is made of the die pad DPC, the bonding material BDC, the insulator ZE, and the metal film ME. The pad PL1 of the semiconductor chip CPL and the die pad DPC are electrically connected via the wire BW1, and the pad PH1 of the semiconductor chip CPH and the metal film ME are electrically connected via the wire BW2. Thereby, the capacitor CP functions as the digital isolator of capacitor type, and the signals can be transmitted between the semiconductor chip CPL and the semiconductor chip CPH via the wire BW1, the capacitor CP, and the wire BW2.

The capacitor CP is made of the die pad DPC, the bonding material BDC on the die pad DPC, the insulator ZE on the bonding material BDC, and the metal film ME on the insulator ZE, and therefore, the cost for forming the capacitor CP can be reduced. Thus, the cost for manufacturing the semiconductor device PKG can be reduced.

A large potential difference may occur between the electrode E1 (the die pad DPC) and the electrode E2 (the metal film ME) in the capacitor CP. In other words, since the large potential difference may occur, the capacitor CP is used for transmitting signals. Thus, it is important to increase the dielectric withstand voltage between the electrode E1 and the electrode E2 in the capacitor CP as high as possible for improving the reliability of the semiconductor device PKG including the semiconductor chips CPH, CPL and the capacitor CP or reliability of an electronic apparatus using the semiconductor device PKG.

In the present first embodiment, the withstand voltage of the capacitor CP can be controlled by adjusting the thickness of the insulator ZE. Specifically, the withstand voltage of the capacitor CP can be increased by increasing the thickness of the insulator ZE. The thickness of the insulator ZE can be easily adjusted, and the capacitor CP with a desired withstand voltage can be easily and accurately formed. The increase in the thickness of the insulator ZE hardy affects the cost of the capacitor CP. Thus, the capacitor CP with a desired withstand voltage can be formed at low cost. The thickness of the insulator ZE may be, for example, 20 μm or more.

The capacitance of the capacitor CP can be controlled by adjusting the outer size (planar dimension) of the metal film ME. Specifically, the capacitance of the capacitor CP can be increased by increasing the outer size of the metal film ME. The outer size of the metal film ME can be easily adjusted, and the capacitor CP with a desired capacitance can be easily and accurately formed.

In the semiconductor device PKG according to the first embodiment, the distance L1 between the die pad DPL and the die pad DPC is smaller than the distance L2 between the die pad DPH and the die pad DPC. Thereby, the reliability of the semiconductor device PKG can be further improved. The reasons for this point will be described below.

The die pad DPC is electrically connected to not the pad PH of the semiconductor chip CPH but the pad PL1 of the semiconductor chip CPL via the wire BW1. Thus, the voltage supplied to the semiconductor chip CPL can be also supplied to the die pad DPL and the die pad DPC, but is not supplied to the die pad DPH. The metal film ME is electrically connected to not the pad PL of the semiconductor chip CPL but the pad PH1 of the semiconductor chip CPH via the wire BW2. Thus, the voltage supplied to the semiconductor chip CPH can be also supplied to the die pad DPH, but is not supplied to the die pad DPC and the die pad DPL. As described with reference to FIG. 1, the semiconductor chip CPL is electrically connected to the low-voltage regions outside the semiconductor device PKG via the wires BW, the leads LD2, and the like, and the semiconductor chip CPH is electrically connected to the high-voltage regions outside the semiconductor device PKG via the wires BW, the leads LD1, and the like. Thus, if the large potential difference occurs between the voltage (the power supply voltage, the reference voltage) supplied to the semiconductor chip CPL and the voltage (the power supply voltage, the reference voltage) supplied to the semiconductor chip CPH, the potential difference between the die pad DPH and the die pad DPC is larger than the potential difference between the die pad DPL and the die pad DPC. That is, there is a risk of occurrence of the large potential difference between the die pad DPH and the die pad DPC. For example, by the supply of the power supply potential V1 of FIG. 1 to the die pad DPH and the supply of the power supply potential V2 of FIG. 1 to the die pad DPC and the die pad DPL, the large potential difference may be caused between the die pad DPH and the die pad DPC.

Therefore, in the first embodiment, the distance L1 between the die pad DPL and the die pad DPC is made smaller than the distance L2 between the die pad DPH and the die pad DPC. In other words, the distance L2 between the die pad DPH and the die pad DPC is made larger than the distance L1 between the die pad DPL and the die pad DPC. Thereby, the withstand voltage between the die pad DPH and the die pad DPC can be made higher than the withstand voltage between the die pad DPL and the die pad DPC. Since the withstand voltage between the die pad DPH and the die pad DPC is increased, failures caused when the large potential difference occurs between the die pad DPH and the die pad DPC can be suppressed or prevented. Since the potential difference is difficult to occur between the die pad DPL and the die pad DPC, the required withstand voltage between the die pad DPL and the die pad DPC is lower than the required withstand voltage between the die pad DPH and the die pad DPC. Thus, the distance L1 between the die pad DPL and the die pad DPC can be made smaller than the distance L2 between the die pad DPH and the die pad DPC. Since the distance L1 between the die pad DPL and the die pad DPC is decreased, the semiconductor device PKG can be downsized. Specifically, the dimension of the semiconductor device PKG in the Y direction can be decreased. Thereby, both of the improvement of the reliability of the semiconductor device PKG and the downsizing of the semiconductor device PKG can be achieved.

### FIRST MODIFICATION EXAMPLE

A first modification example of the steps of FIGS. 9 to 12 will be described.

FIGS. 13 to 16 are cross-sectional views illustrating the first modification example of the steps of manufacturing the semiconductor device PKG.

In the first modification example, a chip CH2 is prepared instead of the chip CH1. The chip CH2 can be prepared as follows.

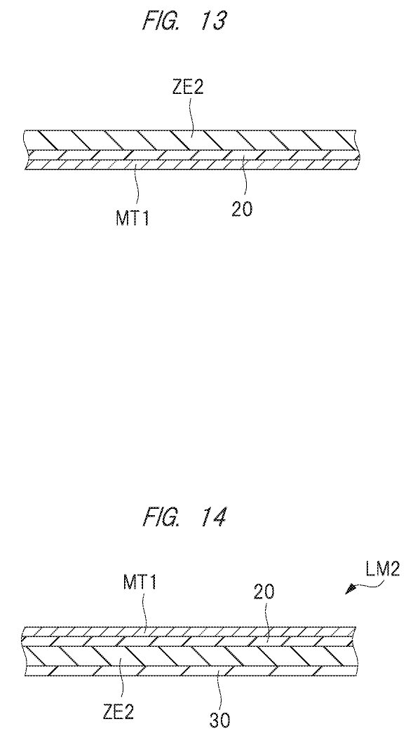

As illustrated in FIG. 13, a DAF 20 is adhered to the metal plate MT1, and then, an insulating substrate ZE2 is adhered to the DAF 20. And, for example, a glass substrate or a resin substrate can be preferably used as the substrate ZE2. Thereafter, a DAF 30 is adhered to the substrate ZE2 as illustrated in FIG. 14. Thereby, a layered material LM2, which is made of the DAF 30, the insulating film ZE2 on the DAF 30, the DAF 20 on the insulating film ZE2, and the metal plate MT1 on the DAF 20, is formed.

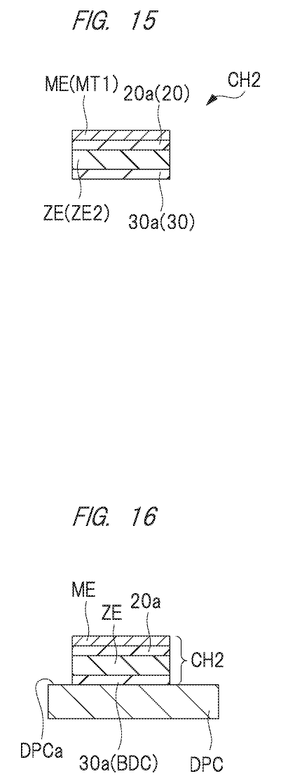

Thereafter, the layered material LM2 is cut into pieces by dicing. Thereby, the chip CH2 can be manufactured as illustrated in FIG. 15. The chip CH2 is made of a DAF30a, the insulator ZE on the DAF 30a, the DAF 20a on the insulating film ZE, and the metal film ME on the DAF 20a. The insulator ZE of the chip CH2 is made of the cut substrate ZE2, the metal film ME of the chip CH2 is made of the cut metal plate MT1, the DAF 20a of the chip CH2 is made of the cut DAF 20, and the DAF 30a of the chip CH2 is made of the cut DAF 30.

Thereafter, the semiconductor chip CPH is arranged on the upper surface DPHa of the die pad DPH in the lead frame via the bonding material BDH, the semiconductor chip CPL is arranged on the upper surface DPLa of the die pad DPL via the bonding material BDL, and the chip CH2 is arranged on the upper surface DPCa of the die pad DPC as illustrated in FIG. 16. At this time, the chip CH2 is arranged such that the DAF 30a faces the die pad DPC. Thereafter, the bonding materials BDH, BDL and the DAFs 20a, 30a are hardened by a thermal processing or the like. The hardened DAF 30a is to be the bonding material BDC. Thereby, the insulator ZE is arranged on the die pad DPC via the bonding material BDC (the DAF 30a in this case), and the metal film ME is arranged on the insulator ZE via the bonding material (the DAF 20a in this case). As can be seen from FIG. 16, in the application of the first modification example, the bonding material (the DAF 20a in this case) is arranged between the insulator ZE and the metal film ME illustrated in FIGS. 7 and 8.

### SECOND MODIFICATION EXAMPLE

A second modification example of the steps of FIGS. 9 to 12 will be described.

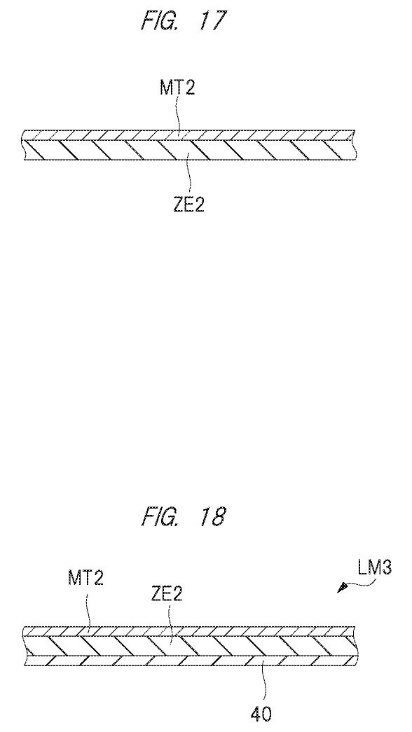

FIGS. 17 to 20 are cross-sectional views illustrating the second modification example of the steps of manufacturing the semiconductor device PKG.

In the second modification example, a chip CH3 is prepared instead of the chip CH1. The chip CH3 can be prepared as follows.

A metal film MT2 is formed on the insulating substrate ZE2 as illustrated in FIG. 17. And, for example, a glass substrate or a resin substrate can be preferably used as the substrate ZE2. The metal film MT2 can be formed by, for example, a sputtering method, a plating method, or a combination of the sputtering method and the plating method. After the metal film MT2 is formed, the substrate ZE2 may be ground to be thinner. Thereafter, a DAF 40 is adhered to the substrate ZE2 as illustrated in FIG. 18. Thereby, a layered material LM3, which is made of the DAF 40, the substrate ZE2 on the DAF 40, and the metal film MT2 on the substrate ZE2, is formed.

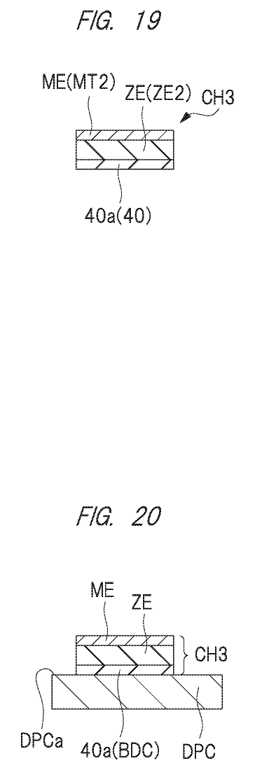

Thereafter, the layered material LM3 is cut into pieces by dicing. Thereby, the chip CH3 can be manufactured as illustrated in FIG. 19. The chip CH3 is made of a DAF40a, the insulator ZE on the DAF 40a, and the metal film ME on the insulator ZE. The insulator ZE of the chip CH3 is made of the cut substrate ZE2, the metal film ME of the chip CH3 is made of the cut metal film MT2, and the DAF 40a of the chip CH3 is made of the cut DAF 40.

Thereafter, the semiconductor chip CPH is arranged on the upper surface DPHa of the die pad DPH in the lead frame via the bonding material BDH, the semiconductor chip CPL is arranged on the upper surface DPLa of the die pad DPL via the bonding material BDL, and the chip CH3 is arranged on the upper surface DPCa of the die pad DPC as illustrated in FIG. 20. At this time, the chip CH3 is arranged such that the DAF 40a faces the die pad DPC. Thereafter, the bonding materials BDH, BDL and the DAF 40a are hardened by a thermal processing or the like. The hardened DAF 40a is to be the bonding material BDC. Thereby, the insulator ZE is arranged on the die pad DPC via the bonding material BDC (the DAF 40a in this case), and the metal film ME is arranged on the insulator ZE.

### THIRD MODIFICATION EXAMPLE

A third modification example of the steps of FIGS. 9 to 12 will be described.

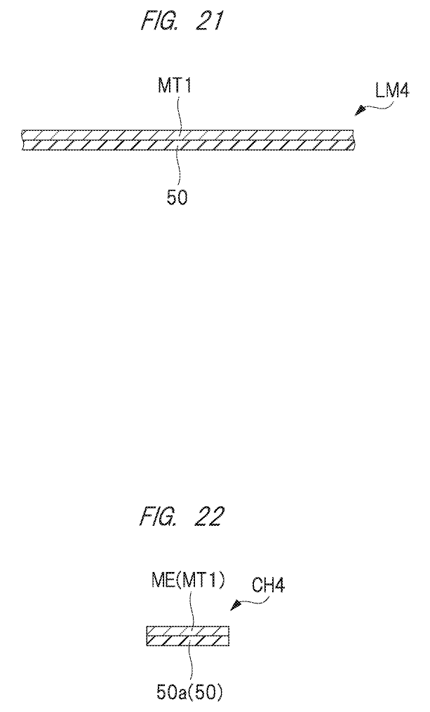

FIGS. 21 to 26 are cross-sectional views illustrating the third modification example of the steps of manufacturing the semiconductor device PKG.

In the third modification example, chips CH4 and CH5 are prepared instead of the chip CH1. The chips CH4 and CH5 can be prepared as follows.

A DAF 50 is adhered to the metal plate MT1 as illustrated in FIG. 21. Thereby, a layered material LM4, which is made of the DAF 50 and the metal plate MT1 on the DAF 50, is formed. Thereafter, the layered material LM4 is cut into pieces by dicing or the like. Thereby, the chip CH4 can be manufactured as illustrated in FIG. 22. The chip CH4 is made of a DAF 50a and the metal film ME on the DAF 50a. The metal film ME of the chip CH4 is made of the cut metal plate MT1.

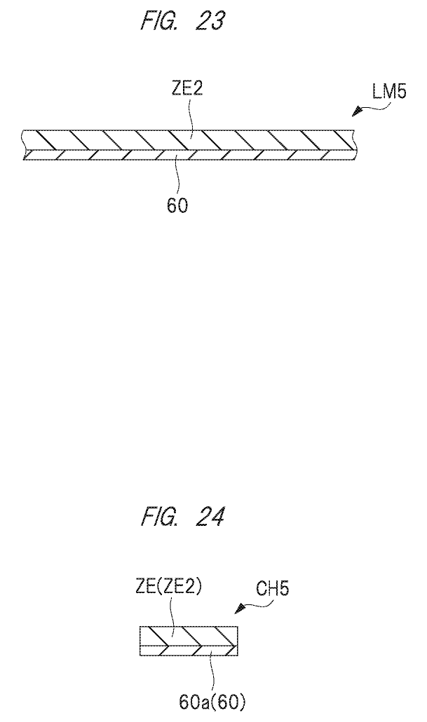

A DAF 60 is adhered to the insulating substrate ZE2 as illustrated in FIG. 23. Thereby, a layered material LM5, which is made of the DAF 60 and the substrate ZE2 on the DAF 60, is formed. Thereafter, the layered material LM5 is cut into pieces by dicing or the like. Thereby, the chip CH5 can be manufactured as illustrated in FIG. 24. The chip CH5 is made of a DAF 60a and the insulator ZE on the DAF 60a. The insulator ZE of the chip CH5 is made of the cut substrate ZE2, and the DAF 60a of the chip CH5 is made of the cut DAF 60.

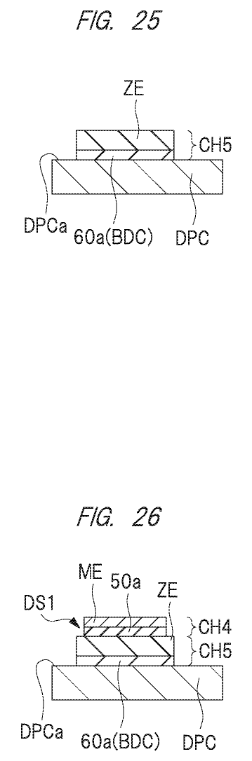

Thereafter, the semiconductor chip CPH is arranged on the upper surface DPHa of the die pad DPH in the lead frame via the bonding material BDH, the semiconductor chip CPL is arranged on the upper surface DPLa of the die pad DPL via the bonding material BDL, and the chips CH4 and CH5 are arranged on the upper surface DPCa of the die pad DPC. At this time, the chip CH5 is arranged on the upper surface DPCa of the die pad DPC as illustrated in FIG. 25, and then, the chip CH4 is arranged on the chip CH5 as illustrated in FIG. 26. The chip CH5 is arranged such that the DAF 60a faces the die pad DPC. The chip CH4 is arranged such that the DAF 50a faces the insulator ZE of the chip CH5. Thereafter, the bonding materials BDH, BDL and the DAFs 50a, 60a are hardened by a thermal processing or the like. The hardened DAF 60a is to be the bonding material BDC. Thereby, the insulator ZE is arranged on the die pad DPC via the bonding material BDC (the DAF 60a in this case), and the metal film ME is arranged on the insulator ZE via the bonding material (the DAF 50a in this case). As can be seen from FIG. 26, in the third modification example, the bonding material (the DAF 50a in this case) is arranged between the insulator ZE and the metal film ME illustrated in FIGS. 7 and 8.

In the application of the steps of FIGS. 13 to 16 (the first modification example), as can be seen from FIG. 16, the outer size of the DAF 20a is almost the same as the outer size of the insulator ZE. The surface asperity is hardly formed on the side surface of the chip CH2.

To the contrary, in the application of the steps of FIGS. 21 to 26 (the third modification example), as can be seen from FIG. 26, the outer size (planar dimension) of the chip CH4 can be made different from the outer size (planar dimension) of the chip CH5. Thus, the outer size (planar dimension) of the insulator ZE can be made different from the outer size (planar dimension) of the DAF 50a.

FIG. 26 corresponds to a case in which the outer size of the chip CH4 is smaller than the outer size of the chip CH5. Thus, in FIG. 26, the outer size of the DAF 50a is smaller than the outer size of the insulator ZE, and surface asperity DS1 is accordingly formed between the side surface of the DAF 50a and the insulator ZE.

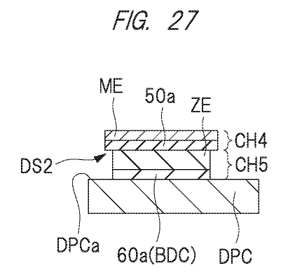

FIG. 27 illustrates the same steps as in FIG. 26, but corresponds to a case in which the outer size of the chip CH4 is larger than the outer size of the chip CH5. Thus, in FIG. 27, the outer size of the DAF 50a is larger than the outer size of the insulator ZE, and surface asperity DS2 is accordingly formed between the side surface of the DAF 50a and the insulator ZE.

A creepage distance between the metal film ME and the die pad DPC can be made larger in the case with the surface asperity DS1 or DS2 as illustrated in FIG. 26 or 27 than the case without the surface asperity DS1 or DS2 (FIG. 16), and thus, the withstand voltage of the capacitor CP can be further increased.

### FOURTH MODIFICATION EXAMPLE

A fourth modification example of the steps of FIGS. 9 to 12 will be described.

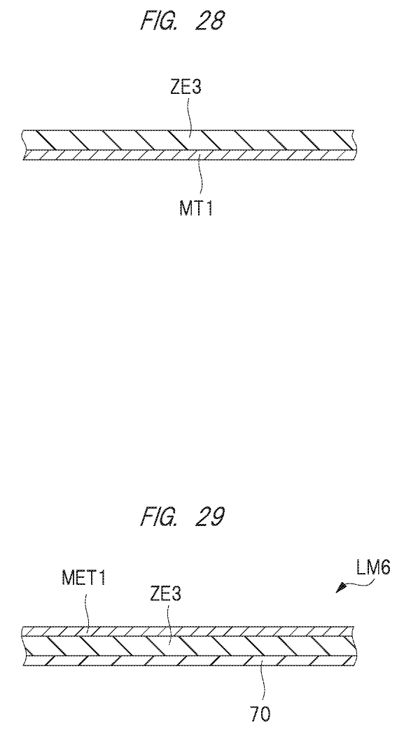

FIGS. 28 to 31 are cross-sectional views illustrating the fourth modification example of the steps of manufacturing the semiconductor device PKG.

In the fourth modification example, a chip CH6 is prepared instead of the chip CH1. The chip CH6 can be prepared as follows.

A mold resin ZE3 is formed on the metal plate MT1 as illustrated in FIG. 28. Thereafter, a DAF 70 is adhered to the mold resin ZE3 as illustrated in FIG. 29. Thereby, a layered material LM6, which is made of the DAF 70, the mold resin ZE3 on the DAF 70, and the metal plate MT1 on the mold resin ZE3, is formed.

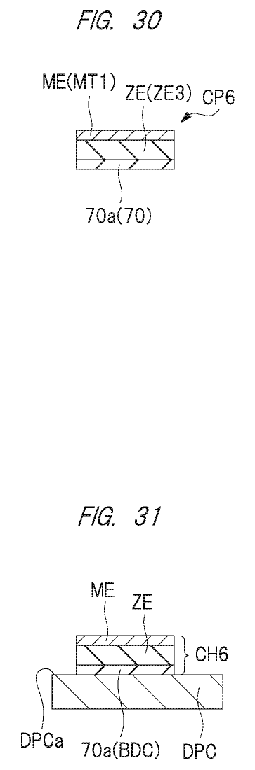

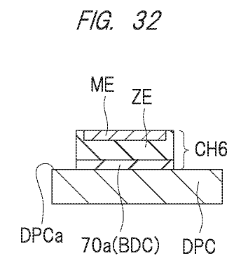

Thereafter, the layered material LM6 is cut into pieces by dicing or the like. Thereby, the chip CH6 can be manufactured as illustrated in FIG. 30. The chip CH6 is made of a DAF 70a, the insulator ZE on the DAF 70a, and the metal film ME on the insulator ZE. The insulator ZE of the chip CH6 is made of the cut mold resin ZE3, the metal film ME of the chip CH6 is made of the cut metal plate MT1, and the DAF 70a of the chip CH6 is made of the cut DAF 70.

Thereafter, the semiconductor chip CPH is arranged on the upper surface DPHa of the die pad DPH in the lead frame via the bonding material BDH, the semiconductor chip CPL is arranged on the upper surface DPLa of the die pad DPL via the bonding material BDL, and the chip CH6 is arranged on the upper surface DPCa of the die pad DPC as illustrated in FIG. 31. At this time, the chip CH6 is arranged such that the DAF 70a faces the die pad DPC. Thereafter, the bonding materials BDH, BDL and the DAF 70a are hardened by a thermal processing or the like. The hardened DAF 70a is to be the bonding material BDC. Thereby, the insulator ZE is arranged on the die pad DPC via the bonding material BDC (the DAF 70a in this case), and the metal film ME is arranged on the insulator ZE.

FIG. 32 illustrates the same steps as in FIG. 31. However, in FIG. 32, the side surfaces of the metal film ME are at least partially covered with the insulator ZE (the mold resin ZE3). This can be achieved when, for example, a metal plate made of coupled rectangular metal parts is used for the metal plate MT1. In this case, the metal film ME is formed by the rectangular metal parts.

When the side surfaces of the metal film ME are at least partially covered with the insulator ZE as illustrated in FIG. 32, the withstand voltage of the capacitor CP can be further increased.

### SECOND EMBODIMENT

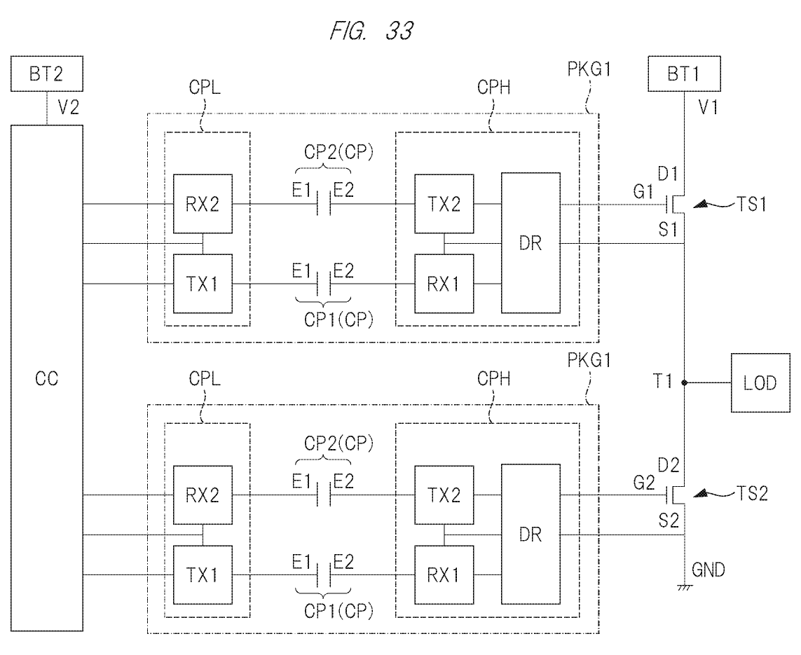

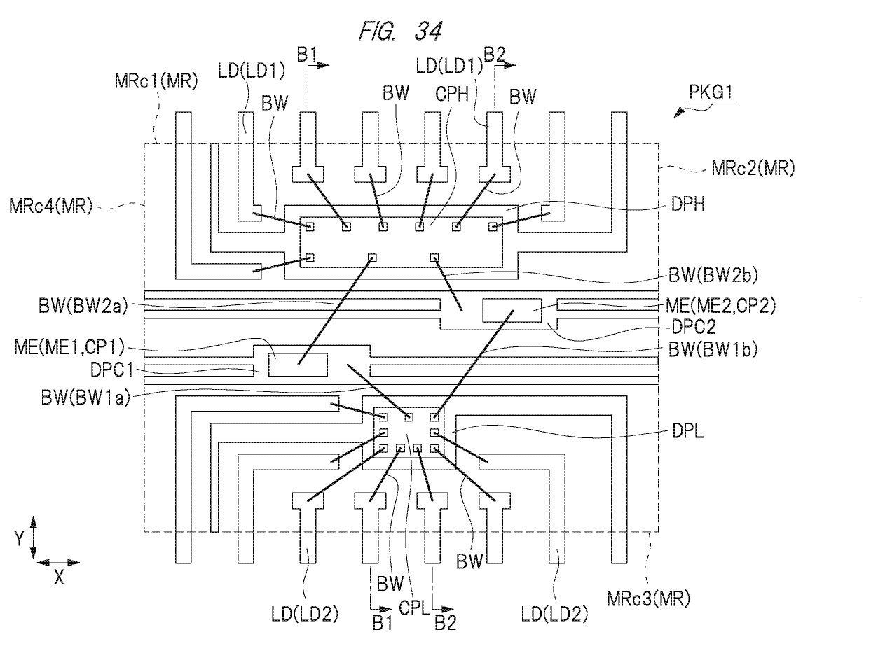

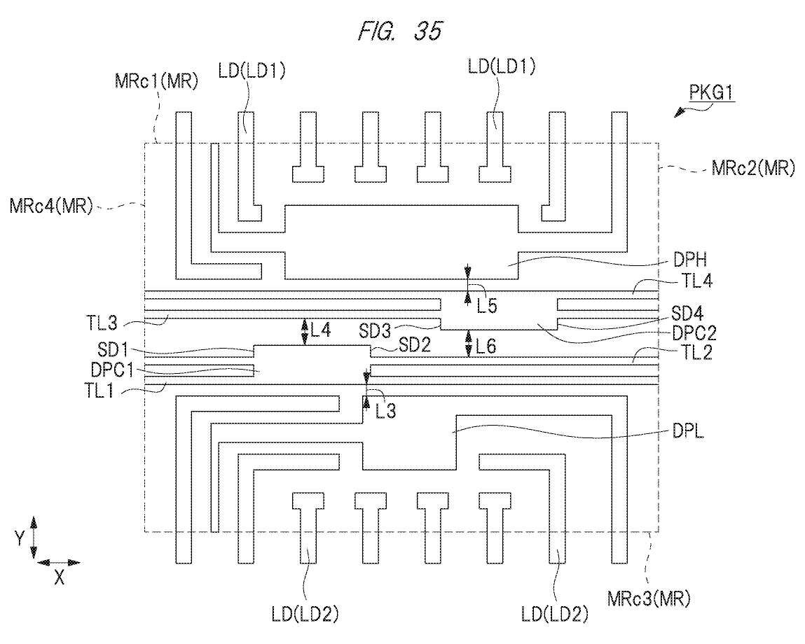

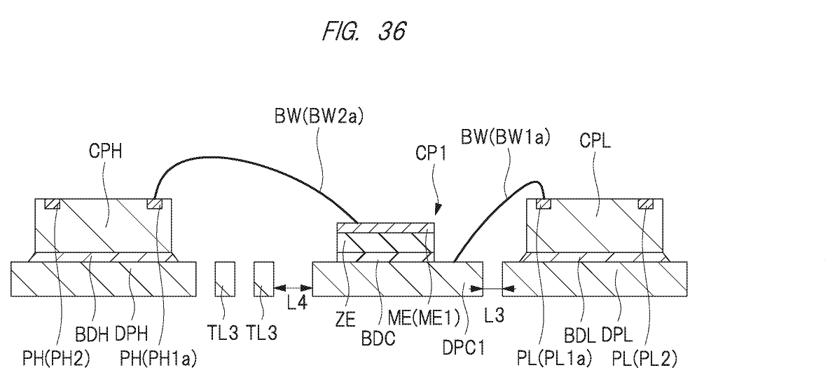

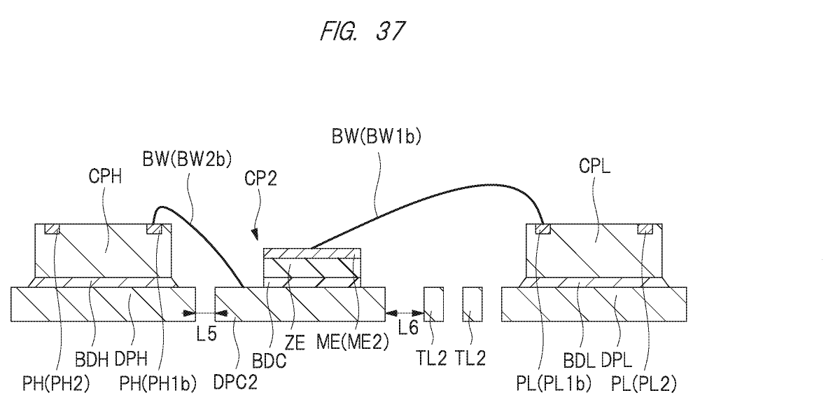

FIG. 33 is a circuit diagram illustrating an inverter circuit using a semiconductor device PKG1 according to a second embodiment, and corresponds to FIG. 1. FIGS. 34 and 35 are perspective plan views illustrating the semiconductor device PKG1 according to the second embodiment. FIG. 34 corresponds to FIG. 3, and FIG. 35 corresponds to FIG. 4. FIGS. 36 and 37 are cross-sectional views schematically illustrating a part of the semiconductor device PKG1, and correspond to FIG. 8. FIG. 36 substantially corresponds to the cross-sectional view of the semiconductor device PKG1 taken along the line B1-B1 of FIG. 34, and FIG. 37 substantially corresponds to the cross-sectional view of the semiconductor device PKG1 taken along the line B2-B2 of FIG. 34. FIG. 36 illustrates how the semiconductor chip CPL, a capacitor CP1, and the semiconductor chip CPH are connected via the wires BW, and FIG. 37 illustrates a connection relation among the semiconductor chip CPL, a capacitor CP2, and the semiconductor chip CPH via the wire BW. The sealing body MR is not illustrated in FIGS. 36 and 37 as in FIG. 8.

The differences in configuration of the semiconductor device PKG1 according to the second embodiment from those of the semiconductor device PKG according to the first embodiment will be mainly described below with reference to FIGS. 33 to 37. The same points of the semiconductor device PKG1 according to the second embodiment as those of the semiconductor device PKG according to the first embodiment will not be repeatedly described.

In the second embodiment, two capacitors CP are formed in the semiconductor device PKG1 as illustrated in FIG. 33. One of the two capacitors CP is referred to as capacitor CP1, and the other is referred to as capacitor CP2. The semiconductor device PKG1 includes two die pads DPC1 and DPC2 instead of the die pad DPC. As illustrated in FIGS. 36 and 37, the semiconductor chip CPH of the semiconductor device PKG1 includes two pads PH1a and PH1b instead of the pad PH1, and the semiconductor chip CPL of the semiconductor device PKG1 includes two pads PL1a and PL1b instead of the pad PL1.

In the second embodiment, not only the transmitter circuit TX1 but also a receiver circuit RX2 are formed in the semiconductor chip CPL as illustrated in FIG. 33. And, not only the receiver circuit RX1 and the driver circuit DR but also a transmitter circuit TX2 are formed in the semiconductor chip CPH.

The capacitors CP are arranged between the transmitter circuit TX1 and the receiver circuit RX1 and between the transmitter circuit TX2 and the receiver circuit RX2, respectively. The capacitor CP which is arranged between the transmitter circuit TX1 and the receiver circuit RX1 is the capacitor CP1, and the capacitor CP which is arranged between the transmitter circuit TX2 and the receiver circuit RX2 is the capacitor CP2. The signal can be transmitted from the transmitter circuit TX1 to the receiver circuit RX1 via the capacitor CP1, and the signals can be transmitted from the transmitter circuit TX2 to the receiver circuit RX2 via the capacitor CP2. Alternatively, a transceiver circuit may be used instead of the transmitter circuit TX2, and a transceiver circuit may be used instead of the receiver circuit RX2.

The die pad DPC1 is a capacitor mounting portion on which a part of the capacitor CP1 is mounted. The die pad DPC2 is a capacitor mounting portion on which a part of the capacitor CP2 is mounted. The die pad DPC1 and the die pad DPC2 are arranged between the die pad DPL and the die pad DPH in the Y direction. The distance (gap) L3 between the die pad DPL and the die pad DPC1 is smaller than the distance (gap) L4 between the die pad DPC1 and a suspending lead TL3 adjacent to the die pad DPC1 and coupled to the die pad DPC2. The distance (gap) L5 between the die pad DPH and the die pad DPC2 is smaller than the distance (gap) L6 between the die pad DPC2 and a suspending lead TL2 adjacent to the die pad DPC2 and coupled to the die pad DPC1. The die pads DPC1 and DPC2 are sealed in the sealing body MR and are not exposed from the sealing body MR.

The configurations of the capacitor CP1 and the capacitor CP2 are basically the same as the configuration of the capacitor CP according to the first embodiment. The capacitor CP1 is made of the die pad DPC1, the bonding material BDC on the die pad DPC1, the insulator ZE, and the metal film ME. The capacitor CP2 is made of the die pad DPC2, the bonding material BDC on the die pad DPC2, the insulator ZE, and the metal film ME. Specifically, the insulator ZE is arranged on the upper surface of the die pad DPC1 via the bonding material BDC, and the metal film ME (referred to as metal film ME1) is arranged on the insulator ZE. The insulator ZE is arranged on the upper surface of the die pad DPC2 via the bonding material BDC, and the metal film ME (referred to as metal film ME2) is arranged on the insulator ZE.

An electrode E1 of the capacitor CP1 is made of the die pad DPC1, and an electrode E2 of the capacitor CP1 is made of the metal film ME1. The capacitive insulating film of the capacitor CP1 is made of the insulator ZE and the insulating bonding material BDC which are arranged between the die pad DPC1 and the metal film ME1. An electrode E1 of the capacitor CP2 is made of the die pad DPC2, and an electrode E2 of the capacitor CP2 is made of the metal film ME2. The capacitive insulating film of the capacitor CP2 is made of the insulator ZE and the insulating bonding material BDC which are arranged between the die pad DPC2 and the metal film ME. If the bonding material BDC is conducting, the bonding material BDC configures a part of the electrode E1.

The pad PL1a of the semiconductor chip CPL is electrically connected to the die pad DPC1 via a wire BW. The wire BW connecting the pad PL1a of the semiconductor chip CPL and the die pad DPC1 is referred to as wire BW1a. That is, one end of the wire BW1a is connected to the pad PL1a of the semiconductor chip CPL, and the other end of the wire BW1a is connected to the die pad DPC1.

The pad PL1b of the semiconductor chip CPL is electrically connected to the metal film ME2 via a wire BW. The wire BW connecting the pad PL1b of the semiconductor chip CPL and the metal film ME2 is referred to as wire BW1b. That is, one end of the wire BW1b is connected to the pad PL1b of the semiconductor chip CPL, and the other end of the wire BW1b is connected to the metal film ME2.

The pad PH1a of the semiconductor chip CPH is electrically connected to the metal film ME1 via a wire BW. The wire BW connecting the pad PH1a of the semiconductor chip CPH and the metal film ME1 is referred to as wire BW2a. That is, one end of the wire BW2a is connected to the pad PH1a of the semiconductor chip CPH, and the other end of the wire BW2a is connected to the metal film ME1.

The pad PH1b of the semiconductor chip CPH is electrically connected to the die pad DPC2 via a wire BW. The wire BW connecting the pad PH1b of the semiconductor chip CPH and the die pad DPC2 is referred to as wire BW2b. That is, one end of the wire BW2b is connected to the pad PH1b of the semiconductor chip CPH, and the other end of the wire BW2b is connected to the die pad DPC2.

The semiconductor device PKG1 according to the second embodiment includes the die pad DPC1, the insulator ZE arranged on the die pard DPC1 via the bonding material BDC, and the metal film ME1 arranged on the insulator ZE. The capacitor CP1 is made of the die pad DPC1, the bonding material BDC, the insulator ZE, and the metal film ME1. The pad PL1a of the semiconductor chip CPL is electrically connected to the die pad DPC1 via the wire BW1a, and the pad PH1a of the semiconductor chip CPH is electrically connected to the metal film ME1 via the wire BW2a. Thereby, the capacitor CP1 functions as the digital isolator of capacitor type, and the signals can be transmitted between the semiconductor chip CPL and the semiconductor chip CPH via the wire BW1a, the capacitor CP1, and the wire BW2a.

The semiconductor device PKG1 includes the die pad DPC2, the insulator ZE arranged on the die pad DPC2 via the bonding material BDC, and the metal film ME2 arranged on the insulator ZE. The capacitor CP2 is made of the die pad DPC2, the bonding material BDC, the insulator ZE, and the metal film ME2. The pad PL1b of the semiconductor chip CPL is electrically connected to the metal film ME2 via the wire BW1b, and the pad PH1b of the semiconductor chip CPH is electrically connected to the die pad DPC2 via the wire BW2b. Thereby, the capacitor CP2 functions as a digital isolator of capacitor type, and the signals can be transmitted between the semiconductor chip CPL and the semiconductor chip CPH via the wire BW1b, the capacitor CP2, and the wire BW2b.

The capacitor CP1 is made of the die pad DPC1, the bonding material BDC on the die pad DPC1, the insulator ZE on the bonding material BDC, and the metal film ME1 on the insulator ZE. The capacitor CP2 is made of the die pad DPC2, the bonding material BDC on the die pad DPC2, the insulator ZE on the bonding material BDC, and the metal film ME2 on the insulator ZE. Thus, the cost for forming the capacitor CP1 and the capacitor CP2 can be reduced. Therefore, the cost for manufacturing the semiconductor device PKG1 can be reduced.

The withstand voltage of the capacitor CP1 can be controlled by adjusting the thickness of the insulator ZE of the capacitor CP1, and the withstand voltage of the capacitor CP2 can be controlled by adjusting the thickness of the insulator ZE of the capacitor CP2. Thus, the capacitors CP1 and CP2 with desired withstand voltages can be easily formed at low cost.

The capacitance of the capacitor CP1 can be controlled by adjusting the outer size of the metal film ME1, and the capacitance of the capacitor CP2 can be controlled by adjusting the outer size of the metal film ME2. Thus, the capacitors CP1 and CP2 with desired capacitance can be easily and accurately formed.

In the semiconductor device PKG1 according to the second embodiment, the distance L3 between the die pad DPL and the die pad DPC1 is smaller than the distance L4 between the suspending lead TL3 and the die pad DPC1. The distance L5 between the die pad DPH and the die pad DPC2 is smaller than the distance L6 between the suspending lead TL2 and the die pad DPC2. This is because the die pad DPC1 is electrically connected to the pad PL1a of the semiconductor chip CPL via the wire BW1a, the metal film ME1 is electrically connected to the pad PH1a of the semiconductor chip CPH via the wire BW2a, the die pad DPC2 is electrically connected to the pad PH1b of the semiconductor chip CPH via the wire BW2b, and the metal film ME2 is electrically connected to the pad PL1b of the semiconductor chip CPL via the wire BW1b. In this case, the voltage supplied to the semiconductor chip CPH can be also supplied to the die pad DPH and the die pad DPC2, but is not supplied to the die pad DPL and the die pad DPC1. Also, the voltage supplied to the semiconductor chip CPL can be also supplied to the die pad DPL and the die pad DPC1, but is not supplied to the die pad DPH and the die pad DPC2. Thus, if the large potential difference occurs between the voltage supplied to the semiconductor chip CPL and the voltage supplied to the semiconductor chip CPH, the potential difference between the die pad DPC1 and the die pad DPC2 is larger than the potential difference between the die pad DPL and the die pad DPC1 and the potential difference between the die pad DPH and the die pad DPC2. That is, there is a risk of occurrence of the large potential difference between the die pad DPC1 and the die pad DPC2. For example, the large potential difference may occur between the die pad DPC1 and the die pad DPC2 when the power supply voltage V1 illustrated in FIG. 1 is supplied to the die pad DPH and the die pad DPC2 while the power supply voltage V2 illustrated in FIG. 1 is supplied to the die pad DPL and the die pad DPC1. The suspending leads TL1 and TL2 are coupled to the die pad DPC1, and thus the potential of the suspending lead TL1 and the potential of the suspending lead TL2 are the same as the potential of the die pad DPC1. The suspending leads TL3 and TL4 are coupled to the die pad DPC2, and thus the potential of the suspending lead TL3 and the potential of the suspending lead TL4 are the same as the potential of the die pad DPC2.

Therefore, the distance L3 between the die pad DPL and the die pad DPC1 is made smaller than the distance L4 between the suspending lead TL3 and the die pad DPC1. In other words, the distance L4 between the suspending lead TL3 and the die pad DPC1 is made larger than the distance L3 between the die pad DPL and the die pad DPC1. The distance L5 between the die pad DPH and the die pad DPC2 is made smaller than the distance L6 between the suspending lead TL2 and the die pad DPC2. In other words, the distance L6 between the suspending lead TL2 and the die pad DPC2 is made larger than the distance L5 between the die pad DPH and the die pad DPC2. Thereby, the withstand voltage “between the die pad DPC1 and the die pad DPC2” can be made larger than the withstand voltages “between the die pad DPH and the die pad DPC2” and “between the die pad DPL and the die pad DPC1” having the small potential difference. Since the withstand voltage “between the die pad DPC1 and the die pad DPC2” is larger, failures caused at the time of the occurrence of the large potential difference between “the die pad DPC1 and the die pad DPC2” can be suppressed or prevented. Also, since the distance L3 “between the die pad DPL and the die pad DPC1” and the distance L5 “between the die pad DPH and the die pad DPC2” are smaller, the semiconductor device PKG1 can be downsized. Thereby, both the improvement of the reliability of the semiconductor device PKG1 and the downsizing of the semiconductor device PKG1 can be achieved.

### THIRD EMBODIMENT

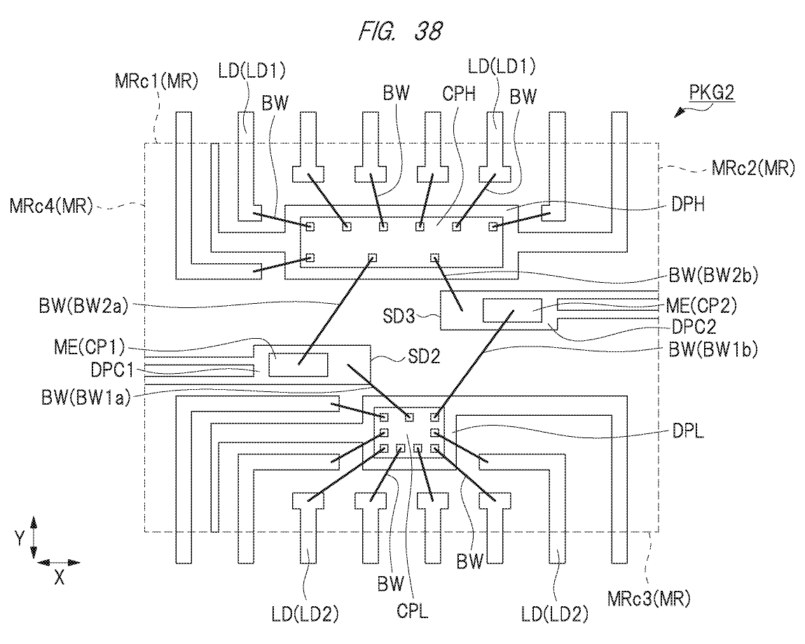

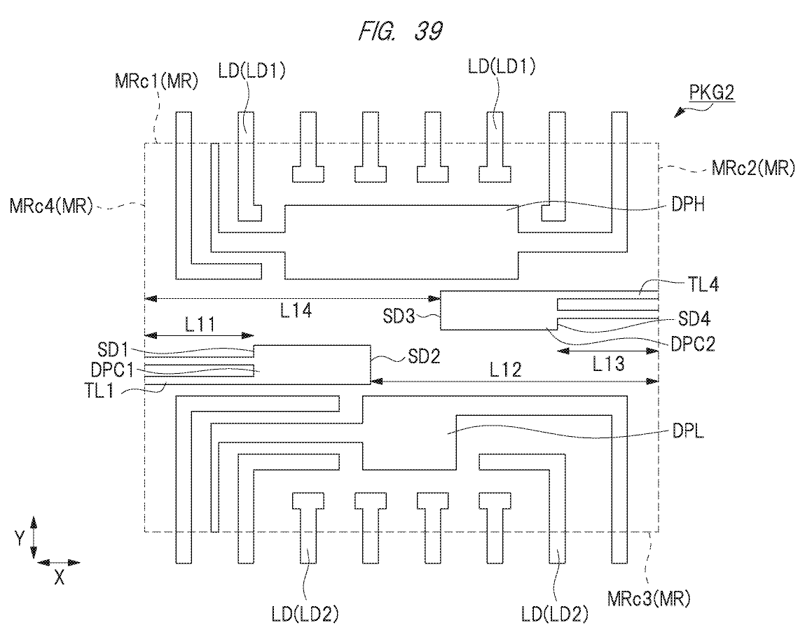

FIGS. 38 and 39 are perspective plan views illustrating a semiconductor device PKG2 according to a third embodiment. FIG. 38 corresponds to FIGS. 34 and 39, corresponds to FIG. 35.

The differences between the semiconductor device PKG1 according to the second embodiment and the semiconductor device PKG2 according to the third embodiment will be described below. The common points between the semiconductor device PKG1 according to the second embodiment and the semiconductor device PKG2 according to the third embodiment will not be repeatedly described.

As can be seen from FIGS. 34 and 35, the semiconductor device PKG1 according to the second embodiment includes the suspending leads TL1 and TL2 integrally coupled to the die pad DPC1 and the suspending leads TL3 and TL4 integrally coupled to the die pad DPC2. The die pad DPC1 has a side surface SD1 and a side surface SD2 opposite to the side surface SD1. The die pad DPC2 has a side surface SD3 and a side surface SD4 opposite to the side surface SD3. The side surface SD1, the side surface SD2, the side surface SD3, and the side surface SD4 are substantially parallel to the Y direction. In the X direction, the side surface SD1 of the die pad DPC1 is positioned between the side surface MRc4 of the sealing body MR and the side surface SD2 of the die pad DPC1. In the X direction, the side surface SD4 of the die pad DPC2 is positioned between the side surface MRc2 of the sealing body MR and the side surface SD3 of the die pad DPC2. In the X direction, the die pad DPC2 is positioned between the side surface MRc2 of the sealing body MR and the die pad DPC1, and the die pad DPC1 is positioned between the side surface MRc4 of the sealing body MR and the die pad DPC2.

The suspending lead TL1 is coupled to the side surface SD1 of the die pad DPC1, and the suspending lead TL2 is coupled to the side surface SD2 of the die pad DPC1. The suspending lead TL1 is sealed in the sealing body MR, and extends between the die pad DPC1 and the side surface MRc4 of the sealing body MR. The suspending lead TL2 is sealed in the sealing body MR, and extends between the die pad DPC1 and the side surface MRc2 of the sealing body MR.

The suspending lead TL3 is coupled to the side surface SD3 of the die pad DPC2, and the suspending lead TL4 is coupled to the side surface SD4 of the die pad DPC2. The suspending lead TL3 is sealed in the sealing body MR, and extends between the die pad DPC2 and the side surface MRc4 of the sealing body MR. The suspending lead TL4 is sealed in the sealing body MR, and extends between the die pad DPC2 and the side surface MRc2 of the sealing body MR. The width of each of the suspending leads TL1, TL2, TL3, and TL4 is preferably as small as possible in order to suppress the parasitic capacitance caused by each of the suspending leads TL1, TL2, TL3, and TL4.

The suspending leads TL1 and TL2 are used to hold the die pad DPC1 onto the lead frame via the suspending leads TL1 and TL2 at the time of the manufacturing of the semiconductor device PKG1. The suspending leads TL3 and TL4 are used to hold the die pad DPC2 onto the lead frame at the time of the manufacturing of the semiconductor device PKG1.

In the semiconductor device PKG1 according to the second embodiment, the die pad DPC1 is held onto the lead frame by the suspending lead TL1 extending between the die pad DPC1 and the side surface MRc4 of the sealing body MR and the suspending lead TL2 extending between the die pad DPC1 and the side surface MRc2 of the sealing body MR. The die pad DPC2 is held onto the lead frame by the suspending lead TL3 extending between the die pad DPC2 and the side surface MRc4 of the sealing body MR and the suspending lead TL4 extending between the die pad DPC2 and the side surface MRc2 of the sealing body MR. Thus, the die pads DPC1 and DPC2 can be stably held at the time of the manufacturing of the semiconductor device PKG1, and thus, the semiconductor device PKG1 is easily manufactured.

To the contrary, as can be seen from FIG. 38 and FIG. 39, the semiconductor device PKG2 according to the third embodiment includes the suspending lead TL1 integrally coupled to the die pad DPC1 and the suspending lead TL4 integrally coupled to the die pad DPC2. The suspending lead TL1 is coupled to the side surface SD1 of the die pad DPC1, and the suspending lead TL4 is coupled to the side surface SD4 of the die pad DPC2. The suspending lead TL1 is sealed in the sealing body MR, and extends between the die pad DPC1 and the side surface MRc4 of the sealing body MR. The suspending lead TL4 is sealed in the sealing body MR, and extends between the die pad DPC2 and the side surface MRc2 of the sealing body MR.

The semiconductor device PKG2 according to the third embodiment does not include the suspending lead TL2 and the suspending lead TL3. Thus, in the semiconductor device PKG2, no suspending lead coupled to the die pad DPC1 is formed between the die pad DPC1 and the side surface MRc2 of the sealing body MR. And, no suspending lead coupled to the die pad DPC2 is formed between the die pad DPC2 and the side surface MRc4 of the sealing body MR. Thus, the parasitic capacitance caused by the suspending leads TL2 and TL3 can be eliminated. Thus, the parasitic capacitance caused in the semiconductor device PKG2 can be decreased.

As can be seen from FIG. 39, the distance L11 between the die pad DPC1 and the side surface MRc4 of the sealing body MR is smaller than the distance L12 between the die pad DPC1 and the side surface MRc2 of the sealing body MR. The distance L13 between the die pad DPC2 and the side surface MRc2 of the sealing body MR is smaller than the distance L14 between the die pad DPC2 and the side surface MRc4 of the sealing body MR. Thereby, in the Y direction, the die pad DPC1 and the suspending lead TL1 do not face the die pad DPC2 and the suspending lead TL4. Consequently, the parasitic capacitance caused in the semiconductor device PKG2 can be efficiently decreased.

In the foregoing, the invention made by the inventors of the present application has been concretely described based on the embodiments. However, it is needless to say that the present invention is not limited to the foregoing embodiments, and various modifications can be made within the scope of the present invention.

What is claimed is:

1. A semiconductor device comprising:
a first die pad;
a second die pad spaced apart from the first die pad;
a third die pad spaced apart from the first die pad and the second die pad;
a first semiconductor chip arranged on the first die pad and including a first pad;
a second semiconductor chip arranged on the second die pad and including a second pad;
an insulator arranged on the third die pad via a first bonding material;
a metal film arranged on the insulator;
a first wire electrically connecting the first pad of the first semiconductor chip and the third die pad;
a second wire electrically connecting the second pad of the second semiconductor chip and the metal film; and
a sealing body sealing the first semiconductor chip, the second semiconductor chip, the first bonding material, the insulator, the metal film, the first die pad, the second die pad, the third die pad, the first wire, and the second wire.

2. The semiconductor device according to claim 1,
wherein a signal is transmitted between the first semiconductor chip and the second semiconductor chip via a capacitor made of the third die pad, the first bonding material, the insulator, and the metal film.

3. The semiconductor device according to claim 1,
wherein the first bonding material is made of a DAF.

4. The semiconductor device according to claim 1, further comprising:
a second bonding material arranged between the first bonding material and the metal film.

5. The semiconductor device according to claim 4,
wherein each of the first bonding material and the second bonding material is made of a DAF.

6. The semiconductor device according to claim 4,
wherein an outer size of the second bonding material is different from an outer size of the insulator.

7. The semiconductor device according to claim 1,
wherein at least a part of a side surface of the metal film is covered with the insulator.

8. The semiconductor device according to claim 1, further comprising:
a plurality of first leads;
a plurality of second leads;
a plurality of third wires; and
a plurality of fourth wires,
wherein the first semiconductor chip further includes a plurality of third pads,
wherein the second semiconductor chip further includes a plurality of fourth pads,
wherein the plurality of third pads of the first semiconductor chip is electrically connected to the plurality of first leads via the plurality of third wires, respectively,
wherein the plurality of fourth pads of the second semiconductor chip is electrically connected to the plurality of second leads via the plurality of fourth wires, respectively, and
wherein a part of each of the plurality of first leads, a part of each of the plurality of second leads, the plurality of third wires, and the plurality of fourth wires are sealed in the sealing body.

9. The semiconductor device according to claim 1,
wherein a distance between the first die pad and the third die pad is smaller than a distance between the second die pad and the third die pad.

10. The semiconductor device according to claim 9,
wherein the third die pad is arranged between the first die pad and the second die pad in plan view.

11. A semiconductor device comprising:
a first die pad;
a second die pad spaced apart from the first die pad;
a third die pad spaced apart from the first die pad and the second die pad;
a fourth die pad spaced apart from the first die pad, the second die pad, and the third die pad;
a first semiconductor chip arranged on the first die pad and including a first pad and a second pad;
a second semiconductor chip arranged on the second die pad and including a third pad and a fourth pad;
a first insulator arranged on the third die pad via a first bonding material;
a first metal film arranged on the first insulator;
a second insulator arranged on the fourth die pad via a second bonding material;
a second metal film arranged on the second insulator;
a first wire electrically connecting the first pad of the first semiconductor chip and the third die pad;
a second wire electrically connecting the second pad of the first semiconductor chip and the second metal film;
a third wire electrically connecting the third pad of the second semiconductor chip and the first metal film;
a fourth wire electrically connecting the fourth pad of the second semiconductor chip and the fourth die pad; and
a sealing body sealing the first semiconductor chip, the second semiconductor chip, the first bonding material, the second bonding material, the first insulator, the second insulator, the first metal film, the second metal film, the first die pad, the second die pad, the third die pad, the fourth die pad, the first wire, the second wire, the third wire, and the fourth wire.

12. The semiconductor device according to claim 11,
wherein a signal is transmitted between the first semiconductor chip and the second semiconductor chip via a first capacitor made of the third die pad, the first bonding material, the first insulator, and the first metal film, and a signal is transmitted between the first semiconductor chip and the second semiconductor chip via a second capacitor made of the fourth die pad, the second bonding material, the second insulator, and the second metal film.

13. The semiconductor device according to claim 11, further comprising:
a first suspending lead and a second suspending lead integrally coupled to the third die pad; and
a third suspending lead and a fourth suspending lead integrally coupled to the fourth die pad,
wherein the sealing body has a first side surface and a second side surface opposite to the first side surface,
wherein the first suspending lead is sealed in the sealing body, and extends between the third die pad and the first side surface of the sealing body,
wherein the second suspending lead is sealed in the sealing body, and extends between the third die pad and the second side surface of the sealing body,
wherein the third suspending lead is sealed in the sealing body, and extends between the fourth die pad and the first side surface of the sealing body, and
wherein the fourth suspending lead is sealed in the sealing body, and extends between the fourth die pad and the second side surface of the sealing body.

14. The semiconductor device according to claim 13,
wherein a distance between the first die pad and the third die pad is smaller than a distance between the third die pad and the third suspending lead, and
wherein a distance between the second die pad and the fourth die pad is smaller than a distance between the fourth die pad and the second suspending lead.

15. The semiconductor device according to claim 11, further comprising:
a first suspending lead integrally coupled to the third die pad; and
a second suspending lead integrally coupled to the fourth die pad,
wherein the sealing body has a first side surface and a second side surface opposite to the first side surface,
wherein the first suspending lead is sealed in the sealing body, and extends between the third die pad and the first side surface of the sealing body,
wherein the second suspending lead is sealed in the sealing body, and extends between the fourth die pad and the second side surface of the sealing body,
wherein no suspending lead coupled to the third die pad is formed between the third die pad and the second side surface of the sealing body, and
wherein no suspending lead coupled to the fourth die pad is formed between the fourth die pad and the first side surface of the sealing body.

16. The semiconductor device according to claim 15,
wherein a distance between the third die pad and the first side surface of the sealing body is smaller than a distance between the third die pad and the second side surface of the sealing body, and
wherein a distance between the fourth die pad and the second side surface of the sealing body is smaller than a distance between the fourth die pad and the first side surface of the sealing body.
